(19) United States
(12) Patent Application Publication
(10) Pub. No.: US 2024/0404788 A1
(43) Pub. Date: Dec. 5, 2024

(54) Pulsed RF Plasma Generator With High Dynamic Range

(71) Applicant: MKS Instruments, Inc., Andover, MA (US)

(72) Inventors: Ky LUU, Victor, NY (US); Aaron RADOMSKI, Conesus, NY (US)

(21) Appl. No.: 18/661,049

(22) Filed: May 10, 2024

Related U.S. Application Data
(60) Provisional application No. 63/538,556, filed on Sep. 15, 2023.
(60) Provisional application No. 63/469,653, filed on May 30, 2023.

(51) Int. Cl. H01J 37/32

(52) U.S. Cl. CPC H01J 37/32146; H01J 37/32183

(57) ABSTRACT

A power generator has a first plurality of power amplifiers each configured to receive a first, common supply voltage and to output a plurality of discrete DC voltages. At least one of the plurality of discrete DC voltages may be varied by varying the first, common supply voltage. The RF power generator may also include a second plurality of power amplifiers receiving a second either common or distinct supply voltage that differs from the first supply voltage. At least one of the plurality of discrete DC voltages may be varied by varying the second common or distinct supply voltage. The output of each power amplifier is added in series to generate an output voltage for the power generator. One of the plurality of power amplifiers is actuated or deactuated at a first time and an other of the plurality of power amplifiers is actuated or deactuated at a second time.

### CROSS-REFERENCE TO RELATED APPLICATIONS

This application claims the benefit of U.S. Provisional Application No. 63/469,653, filed on May 30, 2023, and U.S. Provisional Application No. 63/538,556, filed on Sep. 15, 2023. The entire disclosures of each of the above applications are incorporated herein by reference.

### FIELD

The present disclosure relates to RF generator systems and to control of RF generators.

### BACKGROUND

Plasma processing is frequently used in semiconductor fabrication. In plasma processing, ions are accelerated by an electric field to etch material from or deposit material onto a surface of a substrate. In one basic implementation, the electric field is generated based on Radio Frequency (RF) or Direct Current (DC) power signals generated by a respective RF or DC generator of a power delivery system. The power signals generated by the generator must be precisely controlled to effectively execute plasma etching.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a power generator. The power generator also includes a first plurality of power amplifiers, including a first power amplifier configured to receive a first supply voltage and to output a plurality of DC voltages, and a second power amplifier configured to receive the first supply voltage and to output the plurality of DC voltages. The first power amplifier and the second power amplifier are connected in series, and the power generator generates an output voltage that varies in accordance with a one of the plurality of DC voltages output by the first power amplifier and a one of the plurality of DC voltages output by the second power amplifier. Other embodiments of this aspect include corresponding computer systems, apparatus, and computer programs recorded on one or more computer storage devices, each configured to perform the actions of the methods.

Implementations may include one or more of the following features. The power generator where the first supply voltage varies, and the plurality of DC voltages varies in accordance with the first supply voltage. The voltage output command determines which one of the plurality of DC voltages is output by the selected one of the first plurality of power amplifiers. The first control module is further configured to generate a voltage output command for an other of the first plurality of power amplifiers, where the voltage output command determines which one of the plurality of DC voltages is output by the other of the first plurality of power amplifiers. The first control module receives a clock signal to synchronize operation of the first plurality of power amplifiers. The voltage output command determines which one of the plurality of DC voltages is output by the other of the first plurality of power amplifiers. The first control module and the second control module are configured to receive a clock signal to synchronize operation of the first plurality of power amplifiers. The power generator wherein the first plurality of power amplifiers may include a fixed step generation section of the power generator, and the power generator further may include a variable step generation section including a first variable power amplifier configured to receive a second supply voltage and to output a second plurality of DC voltages that differs from the plurality of DC voltages. The variable step generation section may include a second plurality of power amplifiers including the first variable power amplifier, and a second variable power amplifier configured to receive a third supply voltage and to output a third plurality of DC voltages, where the first variable power amplifier and second variable power amplifier are connected in series, and connected in series with the fixed step generation section, and the power generator generates an output voltage that varies in accordance with a one of the second plurality of DC voltages output by the first variable power amplifier, a one of the third plurality of DC voltages output by the second variable power amplifier, and the output of the fixed step generation section. The first variable power amplifier is configured to receive a second supply voltage and to output a piecewise linear output voltage, and where the first variable power amplifier is connected in series with the fixed step generation section, and the power generator generates an output voltage that varies in accordance with the piecewise linear output voltage and the output voltage of the fixed step generation section. The first variable power amplifier is a piecewise linear power amplifier. The first plurality of power amplifiers outputs a bipolar voltage signal, and the power generator further may include a DC charge pump receiving the output voltage of the first plurality of power amplifiers, and the DC charge pump is configured to convert the bipolar voltage signal to a unipolar voltage signal. The unipolar voltage signal is positive or 0 v, or the unipolar voltage signal is negative or 0 v. Components of the power generator are disposed in one of a remote module or a proximity module, and a proximity module is placed in proximity to a load, and the remote module is placed remotely from the load. The proximity module includes switching components of the first plurality of power amplifiers, and the remote module includes components for generating the first supply voltage. The power generator may include a DC/DC converter, the DC/DC converter configured to receive a rectified voltage and to generate the first supply voltage. The power generator may include a converter configured to receive an ac input voltage, convert the ac input voltage to a rectified DC voltage, and control the rectified DC voltage to the first supply voltage. The converter includes a buck converter that receives the rectified DC voltage and steps down the rectified DC voltage to the first supply voltage. The power generator may include a power supply driver that receives the first supply voltage and generates an alternating direct current signal applied to each of the first plurality of power amplifiers. Each of the first plurality of power amplifiers receives the alternating direct current signal and converts the alternating direct current signal to a rail voltage applied to switches of each of the first plurality of power amplifiers. The plurality of DC voltages includes at least two of +V_{PA}, −V_{PA}, 0 volts, where +V_{PA} and −V_{PA} vary in accordance with the supply voltage. Implementations of the described techniques may include hardware, a method or process, or computer software on a computer-accessible medium.

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions. One general aspect includes a power generator. The power generator also includes a first plurality of power amplifiers, including a first power amplifier configured to receive a first supply voltage and to output a plurality of DC voltages, and a second power amplifier configured to receive the first supply voltage and to output the plurality of DC voltages. The first power amplifier and the second power amplifier are connected in series, and the power generator generates an output voltage that varies in accordance with a one of the plurality of DC voltages output by the first power amplifier and a one of the plurality of DC voltages output by the second power amplifier. One of the plurality of power amplifiers is actuated or deactuated at a first time and an other of the plurality of power amplifiers is actuated or deactuated at a second time, wherein a time delay between the first time and the second time controls one of ringing, overshoot, or power sharing of the output voltage. Other embodiments of this aspect include corresponding computer systems, apparatus, and computer programs recorded on one or more computer storage devices, each configured to perform the actions of the methods.

Implementations may include one or more of the following features. The power generator includes an iterative learning control module for determining the time delay in accordance with a cost function that varies in accordance with selected parameters.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings.

FIG. 1 shows a representation of an inductively coupled plasma processing system;

FIG. 2 shows a representation of a capacitively coupled plasma processing system;

FIG. 3 shows a generalized representation of a plasma system arranged according to various configurations of the present disclosure;

FIG. 4 is a schematic block diagram of a power delivery system having multiple power supplies arranged according to various configurations of the present disclosure;

FIG. 5 shows waveforms of a RF signal and a pulse modulating the RF signal to describe a pulse mode of operation;

FIG. 6 shows a partial schematic block diagram of a power generation system for applying power to a load arranged according to various configurations of the present disclosure;

FIG. 7 shows a partial schematic block diagram of a control system for a power generation system for applying power to a load arranged according to various configurations of the present disclosure;

FIG. 8 shows a partial schematic block diagram of a power amplifier module of a power generation system arranged according to various configurations of the present disclosure;

FIG. 9 shows waveforms depicting operation of a power generation system arranged according to various configurations of the present disclosure;

FIG. 10 shows waveforms depicting operation of a power generation system arranged according to various configurations of the present disclosure;

FIG. 11 shows a partial schematic block diagram of a power amplifier module of a power generation system arranged according to various configurations of the present disclosure, including power amplifier modules receiving varying supply voltages to generate varying output voltages;

FIG. 12 shows a partial schematic block diagram of a power amplifier module of a power generation system arranged according to various configurations of the present disclosure, including weighted power supplies to generate varying output voltages;

FIG. 13 shows a partial schematic block diagram of a power amplifier module of a power generation system arranged according to various configurations of the present disclosure, including a piecewise linear power amplifier to generate varying output voltages;

FIG. 14 shows a partial schematic block diagram of a power amplifier module of a power generation system arranged according to various configurations of the present disclosure to generate a unipolar output voltage;

FIG. 15 shows a partial schematic block diagram of a control system for a power generation system for applying power to a load including a proximity module and remote module arranged according to various configurations of the present disclosure;

FIG. 16 shows waveforms depicting operation during turn-off of power amplifier modules of a power generation system arranged according to various configurations of the present disclosure;

FIG. 17 shows a functional block diagram of an example control module arranged in accordance with various configurations;

FIG. 18 shows a flow chart of operation of a control system arranged in accordance with the principals of the present disclosure;

FIG. 19 shows a waveform depicting operation during turn-off of power amplifier modules of a power generation system arranged according to various configurations of the present disclosure;

FIG. 20 shows an expanded view of a portion of the waveform of FIG. 19 taken along the line 20-20 of FIG. 19;

FIG. 21 shows waveforms depicting the relative actuation and deactuation of selected power amplifier modules of a power generation system and the resultant output voltage of the power generation system;

FIG. 22 shows waveforms depicting the relative actuation and deactuation of selected power amplifier modules of a power generation system and the resultant output voltage of the power generation system when the power amplifier modules are actuated and deactuated in closer proximity in time than the power amplifier modules corresponding to FIG. 16;

FIG. 23 shows multiple waveforms of a single pulse as the power amplifier modules are actuated and deactuated at different intervals; and

FIG. 24 shows a flow chart of operation of a control system arranged in accordance with the principals of the present disclosure.

In the drawings, reference numbers may be reused to identify similar and/or identical elements.

### DETAILED DESCRIPTION

A power system may include a DC or RF power generator or DC or RF generator, a matching network, and a load (such as a process chamber, a plasma chamber, or a reactor having a fixed or variable impedance). The power generator generates a DC or RF power signal, which is received by the matching network or impedance optimizing controller or circuit. The matching network or impedance optimizing controller or circuit transforms a load impedance to a characteristic impedance of a transmission line between the power generator and the matching network. The impedance matching aids in maximizing an amount of power forwarded to the load (“forward power”) and minimizing an amount of power reflected back from the load to the power generator (“reverse power” or “reflected power”). Delivered power to the load may be maximized by minimizing reflected power when the input impedance of the matching network matches the characteristic impedance of the transmission line and generator.

In the power source or power supply field, there are typically two approaches to applying a power signal to the load. A first, more traditional approach is to apply a continuous power signal to the load. In a continuous mode or continuous wave mode, a continuous power signal is typically a constant DC or sinusoidal power signal, which may be a RF or other power signal, that is output continuously by the power source to the load. In the continuous mode approach, the power signal assumes a constant DC or sinusoidal output, and the amplitude of the power signal and/or frequency (of a RF power signal) can be varied in order to vary the output power applied to the load.

A second approach to applying the power signal to the load involves pulsing a voltage, current, or power signal, rather than applying a continuous voltage, current, or power signal to the load. In a pulse or pulsed mode of operation, a voltage, current, or power signal is modulated by a modulation signal in order to define an envelope for the modulated power signal. The voltage, current, or power signal may be, for example, a sinusoidal RF signal or other time varying signal. Power delivered to the load is typically varied by varying the modulation signal.

In a typical power supply configuration, output power applied to the load is determined by using sensors that measure the forward and reflected power or the voltage and current of the voltage, current, or power signal applied to the load. Either set of these signals is analyzed in a control loop. The analysis typically determines a voltage, current, or power value which is used to adjust the output of the power supply in order to vary the voltage, current, or power applied to the load. In a power delivery system where the load is a process chamber or other nonlinear or time varying load, the varying impedance of the load causes a corresponding varying of voltage, current, or power applied to the load, as applied voltage, current, or power is in part a function of the impedance of the load.

In systems where fabrication of various devices relies upon introduction of voltage, current, or power to a load to control a fabrication process, voltage, current, or is typically delivered in one of two configurations. In a first configuration, voltage, current, or power is capacitively coupled to the load. Such systems are referred to as capacitively coupled plasma (CCP) systems. In a second configuration, voltage, current, or power is inductively coupled to the load. Such systems are typically referred to as inductively coupled plasma (ICP) systems. Coupling to the plasma can also be achieved via wave coupling at microwave frequencies. Such an approach typically uses Electron Cyclotron Resonance (ECR) or microwave sources. Helicon sources are another form of wave coupled sources and typically operate at frequencies similar to that of conventional ICP and CCP systems. In various configurations, the Helicon sources may operate at RF frequencies. Power delivery systems may include at least one bias power and/or a source power applied to one or a plurality of electrodes of the load. The source power typically generates a plasma and controls plasma density, and the bias power modulates ions in the formulation of the sheath. The bias and the source may share the same electrode or may use separate electrodes, in accordance with various design considerations.

When a power delivery system drives a time-varying or nonlinear load, such as a process chamber or plasma chamber, the power absorbed by the bulk plasma and plasma sheath results in a density of ions with a range of ion energy. One characteristic measure of ion energy is the ion energy distribution function (IEDF). The ion energy distribution function (IEDF) can be controlled with the bias power or voltage. One way of controlling the IEDF for a system in which multiple voltage, current, or power signals are applied to the load occurs by varying multiple voltage, current, or power signals that are related by at least one of amplitude, frequency, and phase. The related at least one of amplitude, frequency, and phase of multiple voltage, current, or power signals may also be related by a Fourier series and the associated coefficients. The frequencies between the multiple voltage, current, or power signals may be locked, and the relative phase between the multiple voltage, current, or power signals may also be locked. Examples of such systems can be found with reference to U.S. Pat. Nos. 7,602,127; 8,110,991; and 8,395,322, all assigned to the assignee of the present application and incorporated by reference in this application.

Time varying or nonlinear loads may be present in various applications. In one application, plasma processing systems may also include components for plasma generation and control. One such component is a nonlinear load implemented as a process chamber, such as a plasma chamber or reactor. A typical plasma chamber or reactor utilized in plasma processing systems, such as by way of example, for thin-film manufacturing, can utilize a dual power system. One voltage, current, or power generator (the source) controls the generation of the plasma, and the other power voltage, current, or power generator (the bias) controls ion energy. Examples of dual power systems include systems that are described in U.S. Pat. Nos. 7,602,127; 8,110,991; and 8,395,322, referenced above. The dual power system described in the above-referenced patents employs a closed-loop control system to adapt power supply operation for the purpose of controlling ion density and its corresponding ion energy distribution function (IEDF).

Multiple approaches exist for controlling a process chamber, such as may be used for generating plasmas. For example, in voltage, current, or power delivery systems, phase and frequency of multiple driving signals operating at the same or nearly the same frequency may be used to control plasma generation. For such driven plasma sources, the periodic waveform affecting plasma sheath dynamics and the corresponding ion energy are generally known and are controlled by the frequency of the periodic waveforms and the associated phase interaction. Another approach in voltage, current, or power delivery systems involves dual frequency control. That is, two frequency sources operating at different frequencies are used to power a plasma chamber to provide substantially independent control of ion and electron densities. In various configurations, the frequency may be a RF frequency.

Another approach utilizes wideband RF power sources to drive a plasma chamber. A wideband approach presents certain challenges. One challenge is coupling the power to the electrode. A second challenge is that the transfer function of the generated waveform to the actual sheath voltage for a desired IEDF must be formulated for a wide process space to support material surface interaction. In one responsive approach in an inductively coupled plasma system, controlling power applied to a source electrode controls the plasma density while controlling power applied to the bias electrode modulates ions to control the IEDF to provide etch rate and etch feature profile control. By using source electrode and bias electrode control, the etch rate and other various etch characteristics are controlled via the ion density and energy.

As integrated circuit and device fabrication continues to evolve, so do the power requirements for controlling the process for fabrication. For example, with memory device fabrication, the requirements for bias voltage, current, or power continue to increase. Increased voltage, current, or power generates higher and more energetic ions for increased directionality or anisotropic etch feature profiles and faster surface interaction, thereby increasing the etch rate and allowing higher aspect ratio features to be etched. In one nonlimiting example, in some voltage, current, or power delivery systems, increased ion energy is sometimes accompanied by a lower bias frequency requirement along with an increase in the power and number of bias power sources coupled to the plasma sheath created in the plasma chamber. The increased power at a lower bias frequency and the increased number of bias power sources results in intermodulation distortion (IMD) from a sheath modulation. The IMD emissions can significantly reduce power delivered by the source where plasma generation occurs. U.S. Pat. No. 10,821,542, issued Nov. 3, 2020, entitled Pulse Synchronization by Monitoring Power in Another Frequency Band, assigned to the assignee of the present application, and incorporated by reference herein, describes a method of pulse synchronization by monitoring power in another frequency band. In the referenced U.S. patent application, the pulsing of a second RF generator is controlled in accordance with detecting at the second RF generator the pulsing of a first RF generator, thereby synchronizing pulsing between the two RF generators.

The manufacture of modern high performance memory devices such as 3D NAND (nonvolatile) flash and dynamic random access memory (DRAM) requires the capability to precisely etch extremely high aspect ratio (HAR) features, typically having a height to width ratio (height:width) of greater than 50:1. The bias generator is an important component of a semiconductor processing system used for HAR etching. The bias generator desirably is configured to provide a pulsed carrier waveform and to modulate the carrier waveform at a lower frequency. The pulsed bias waveform is used to create a monoenergetic Ion Energy Distribution Function (IEDF), and modulation of the waveform is used to alternate between high energy ion-assisted etching of the memory structure and low energy polymer formation to protect the HAR feature sidewalls. Further, wafer fabrication floorspace is expensive and, therefore, is at a premium. Typically, increasing bias power requirements have caused an increase in fabrication floorspace requirements. Thus, it is desirable to provide a bias generator that provides a pulsed carrier waveform and modulates the carrier waveform at a lower frequency. It is further desirable that the bias generator consume limited floor space in the wafer fabrication environment.

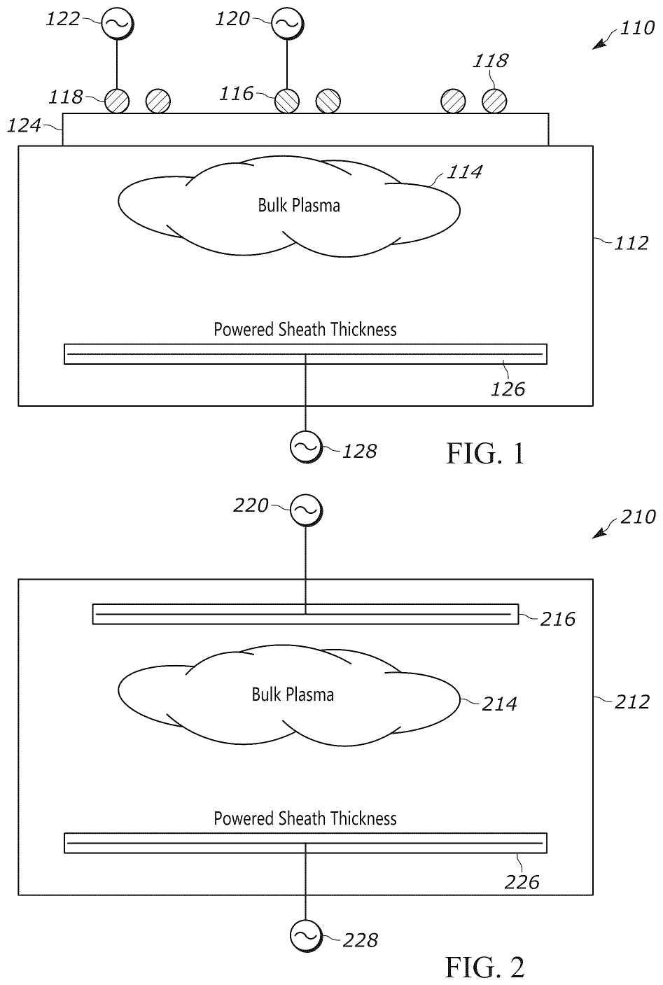

FIG. 1 depicts a representation of an inductively coupled plasma (ICP) system 110. ICP system 110 includes a nonlinear load, such as a reactor, plasma reactor, or plasma chamber 112, which will be referred to interchangeably herein, for generating plasma 114. Power in the form of voltage or current is applied to plasma chamber 112 via a pair of coils, including a coil assembly that in various configurations includes one or multiple coils arranged in various configurations. In one nonlimiting arrangement shown in FIG. 1, plasma chamber 112 includes one or both a first coil 116 and a second coil 118. In various configurations, multiple coils may be arranged concentrically, intertwined, or in a spiral configuration. Power is applied to first coil 116 via power source or RF power generator 120, and power is applied to second coil 118 via power source or RF power generator 122. Coils 116 and 118 are arranged to provide power to plasma chamber 112. A dielectric window 124 enables power to couple through to the plasma while providing a vacuum seal. A substrate 126 is placed in plasma chamber 112 and typically forms the work piece that is the subject of plasma operations. An power supply, power source, or RF power generator 128 (the terms may be used herein interchangeably to refer to an appropriately configured power supply, source, or generator) applies power to plasma chamber 112 via substrate 126.

In various configurations, power sources 120, 122 provide a source voltage or current to ignite or generate plasma 114 or control the plasma density. Also in various configurations, power source 128 provides a bias voltage or current that modulates the ions to control the ion potential or ion energy of plasma 114. In various configurations, power sources 120, 122 are locked to operate at the same frequency, voltage, and current, with fixed or varying relative phases. In various other configurations, power sources 120, 122 may operate at different frequencies, voltages, and currents, and relative phases.

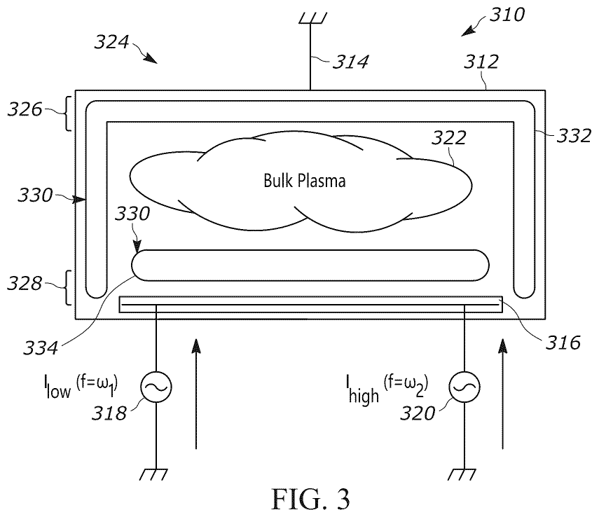

FIG. 2 depicts a representation of a capacitively coupled plasma (CCP) system 210. CCP system 210 includes plasma chamber 212 for generating plasma 214. A pair of electrodes 216, 226 placed within plasma chamber 212 connect to respective DC (ω=0) power sources or RF power generators 220, 228, which may generate a DC signal or other voltage, current, or power signals having one or more of varying amplitude, frequency, or duty cycle, including, but not limited to, a RF signal. In various configurations, power source 220 provides a source voltage or current to ignite or generate plasma 214 or control the plasma density, although a bias power source may also be used to ignite a plasma. In various configurations, power source 228 provides a bias voltage or current that modulates the ions in the plasma to control ion potential, ion energy, or ion density of the plasma 214. In various CCP configurations, bias power and source power may be applied to the upper electrode, such as electrode 216, and the lower electrode, such as electrode 226, in various combinations. In another nonlimiting example, bias power and source power may be applied to a lower electrode, such as electrode 226, and the top electrode, such as electrode 216, is grounded or floating. In various configurations, power sources 220, 228 operate at relative phases when the sources are harmonically related. In various other configurations, power sources 220, 228 operate at different frequencies, voltages, and currents, with fixed or varying relative phases. Also in various configurations, power sources 220, 228 can be connected to the same electrode, while the counter electrode is connected to ground or to yet a third DC (ω=0), or other voltage, current, or power sources having one or more of a varying amplitude, frequency, or duty cycle generator (not shown), including, but not limited to, a RF signal.

In addition to a sinusoidal bias waveform, in various configurations, a nonsinusoidal bias waveform may control ion energy. By way of nonlimiting example, the bias waveform may be a RF waveform, a pulsed rectangular waveform, or a piecewise linear waveform as described in U.S. Pat. No. 10,396,601, issued on Aug. 27, 2019, entitled Piecewise RF Power Systems and Methods for Supplying Pre-Distorted RF Bias Voltage Signals to an Electrode in a Processing Chamber, assigned to the assignee of the present application, and incorporated by reference herein. In various configurations, the bias waveform may be any of a voltage, current, or power waveform having one or more of a varying amplitude, frequency, or duty cycle. In various configurations, a radio frequency (RF) signal may be considered as having a frequency in the range of approximately 2 kHz to 300 GHz.

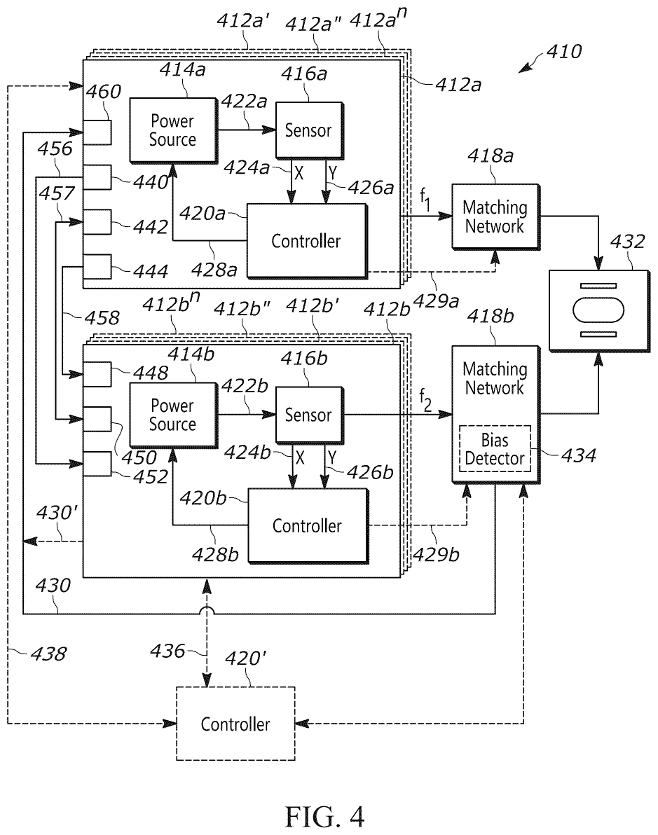

FIG. 3 depicts a cross-sectional view of a generalized representation of a dual power input plasma system 310. Plasma system 310 includes first electrode 312 connected to ground 314 and second electrode 316 spaced apart from first electrode 312. A first power source 318 generates a first voltage, current, or power signal as described above applied to second electrode 316 at a first frequency f=ω₁. A second power source 320 generates a second DC (ω=0) or RF power applied to second electrode 316. In various configurations, second power source 320 operates at a second frequency f=ω₂, where ω₂=nω that is the n^{th} harmonic frequency of the frequency of first power source 318. In various other configurations, second power source 320 operates at a frequency that is not a multiple of the frequency of the first power source 318.

Coordinated operation of respective power sources 318, 320 results in generation and control of plasma 322. As shown in FIG. 3 in schematic view, plasma 322 is formed within an asymmetric sheath 330 of plasma chamber 324. Sheath 330 includes a ground or grounded sheath 332 and a powered sheath 334. A sheath is generally described as the surface area surrounding plasma 322. As can be seen in schematic view in FIG. 3, grounded sheath 332 has a relatively large surface area 326. Powered sheath 334 has a small surface area 328. Because each sheath 332, 334 functions as a dielectric between the conductive plasma 322 and respective electrodes 312, 316, each sheath 332, 334 forms a capacitance between plasma 322 and respective electrodes 312, 316.

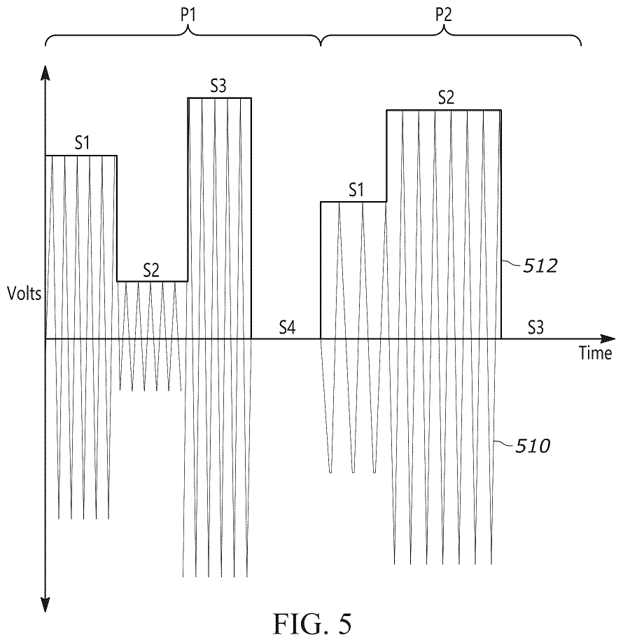

FIG. 4 depicts a RF generator or power supply system 410. Power supply system 410 includes a pair of voltage current, or power generators or power supplies 412a, 412b, matching networks 418a, 418b, and load 432, such as a nonlinear load, which may be a plasma chamber, plasma reactor, process chamber, and the like. In various configurations, generator 412a is referred to as a source generator or power supply, and matching network 418a is referred to as a source matching network. Further, in various configurations, one or both of voltage current, or power generators or power supplies 412a, 412b may output a continuous or pulsed RF voltage signal. Also in various configurations, generator 412b is referred to as a bias generator or power supply, and matching network 418b is referred to as a bias matching network. It will be understood that components can be referenced individually or collectively using the reference number with or without a letter subscript or a prime symbol. In various configurations, one or both of matching networks 418a, 418b may be implemented as a RF blocking filter, rather than an impedance match, such as may be the case for a matching network receiving a pulsed DC or nonsinusoidal signal. In various other configurations, one or both of matching networks 418a, 418b may be omitted.

In various configurations, source generator 412a receives a control signal 430 from matching network 418b, generator 412b, or a control signal 430′ from bias generator 412b. Control signals 430 or 430′ represent an input signal to source generator 412a that indicates one or more operating characteristics or parameters of bias generator 412b. In various configurations, a synchronization bias detector 434 senses the signal output from matching network 418b to load 432 and outputs synchronization or trigger signal 430 to source RF generator 412a. In various configurations, synchronization or trigger signal 430′ may be output from bias generator 412b to source generator 412a, rather than trigger signal 430. A difference between trigger or synchronization signals 430, 430′ may result from the effect of matching network 418b, which can adjust the phase between the input signal to and output signal from matching network. Signals 430, 430′ include information about the operation of bias RF generator 412b that in various configurations enables predictive responsiveness to address periodic fluctuations in the impedance of plasma chamber or load 432 caused by the bias generator 412b. When control signals 430 or 430′ are absent, generators 412a, 412b operate autonomously.

Generators 412a, 412b include respective power sources or amplifiers 414a, 414b, sensors 416a, 416b, and processors, controllers, or control modules 420a, 420b. Power sources 414a, 414b generate respective voltage, current, or power signals 422a, 422b, various configurations of which are described above, output to respective sensors 416a, 416b. Signals 422a, 422b pass through sensors 416a, 416b and are provided to matching networks 418a, 418b as respective power signals f₁ and f₂. Sensors 416a, 416b output signals that vary in accordance with various parameters sensed from load 432. While sensors 416a, 416b, are shown within respective generators 412a, 412b, sensors 416a, 416b can be located externally to generators 412a, 412b. Such external sensing can occur at the output of the generator, at the input of an impedance matching device located between the generator and the load, or between the output of the impedance matching device (including within the impedance matching device) and the load.

Sensors 416a, 416b detect various operating parameters and output signals X and Y. Sensors 416a, 416b may include voltage, current, and/or directional coupler sensors. Sensors 416a, 416b may detect (i) voltage V and current I and/or (ii) forward power P_{FWD} output from respective power amplifiers 414a, 414b and/or generators 412a, 412b and reverse or reflected power P_{REV} received from respective matching networks 418a, 418b or load 432 connected to respective sensors 416a, 416b. The voltage V, current I, forward power P_{FWD}, and reverse power P_{REV} may be scaled, filtered, or scaled and filtered versions of the actual voltage, current, forward power, and reverse power associated with the respective power sources 414a, 414b. Sensors 416a, 416b may be analog or digital sensors or a combination thereof. In a digital implementation, the sensors 416a, 416b may include analog-to-digital (A/D) converters and signal sampling components with corresponding sampling rates. Signals X and Y can represent any of the voltage V and current I or forward (or source) power P_{FWD} reverse (or reflected) power P_{REV}.

Sensors 416a, 416b generate sensor signals X, Y, which are received by respective controllers or control modules 420a, 420b. Control modules 420a, 420b process the respective X, Y signals 424a, 426a and signals 424b, 426b and generate one or a plurality of feedforward or feedback control signals 428a, 428b to respective power sources 414a, 414b. Power sources 414a, 414b adjust voltage, current, or power signals 422a, 422b based on the received one or plurality feedback or feedforward control signal. In various configurations, control modules 420a, 420b may control matching networks 418a, 418b, respectively, via respective control signals 429a, 429b based on, for example, X, Y signals 424a, 426a and signals 424b, 426b. Control modules 420a, 420b may include one or more proportional-integral (PI), proportional-integral-derivative (PID), linear-quadratic-regulator (LQR) controllers or subsets thereof and/or direct digital synthesis (DDS) component(s) and/or any of the various components described below in connection with the modules.

In various configurations, control modules 420a, 420b may include functions, processes, processors, or submodules. Control signals 428a, 428b may be control or actuator drive signals and may communicate DC offset or rail voltage, voltage or current magnitude, frequency, and phase components, and the like. In various configurations, feedback control signals 428a, 428b can be used as inputs to one or multiple control loops. In various configurations, the multiple control loops can include a proportional-integral (PI), proportional-integral-derivative (PID) controllers, linear-quadratic-regulator (LQR) control loops, or subsets thereof, for RF drive, and for power supply rail voltage. In various configurations, control signals 428a, 428b can be used in one or both of a single-input-single-output (SISO) or multiple-input-multiple-output (MIMO) control scheme. An example of a MIMO control scheme can be found with reference to U.S. Pat. No. 10,546,724, issued on Jan. 28, 2020, entitled Pulsed Bidirectional Radio Frequency Source/Load, assigned to the assignee of the present application, and incorporated by reference herein. In other configurations, signals 428a, 428b can provide feedforward control as described in U.S. Pat. No. 10,049,857, issued Aug. 14, 2018, entitled Adaptive Periodic Waveform Controller, assigned to the assignee of the present application, and incorporated by reference herein.

In various configurations, power supply system 410 can include controller 420′. Controller 420′ may be disposed externally to either or both of generators 412a, 412b and may be referred to as external or common controller 420′. In various configurations, controller 420′ may implement one or a plurality of functions, processes, or algorithms described herein with respect to one or both of controllers 420a, 420b. Accordingly, controller 420′ communicates with respective generators 412a, 412b via a pair of respective links 436, 438 which enable exchange of data and control signals, as appropriate, between controller 420′ and generators 412a, 412b. For the various configurations, controllers 420a, 420b, 420′ can distributively and cooperatively provide analysis and control of generators 412a, 412b. In various other configurations, controller 420′ can provide control of generators 412a, 412b, eliminating the need for the respective local controllers 420a, 420b.

In various configurations, power source 414a, sensor 416a, controller 420a, and matching network 418a can be referred to as source power source 414a, source sensor 416a, source controller 420a, and source matching network 418a, respectively. Similarly in various configurations, power source 414b, sensor 416b, controller 420b, and matching network 418b can be referred to as bias power source 414b, bias sensor 416b, bias controller 420b, and bias matching network 418b, respectively. In various configurations and as described above, the source term refers to the generator or voltage, current, or power source that generates a plasma, and the bias term refers to the generator or voltage, current, or power source that tunes ion potential and the Ion Energy Distribution Function (IEDF) of the plasma. In various configurations, the source and bias power supplies operate at different frequencies or duty cycles. In various configurations, the source power supply operates at a higher frequency or duty cycle than the bias power supply. In various other configurations, the source and bias power supplies operate at the same frequencies or duty cycles or substantially the same frequencies or duty cycles.

According to various configurations, source generator 412a and bias generator 412b include multiple ports to communicate externally. Source generator 412a includes pulse envelope synchronization output port 440, digital communication port 442, output port 444, and control signal port 460. Bias generator 412b includes input port 448, digital communication port 450, and pulse synchronization input port 452. Pulse synchronization output port 440 outputs a pulse synchronization signal 456 to pulse synchronization input port 452 of bias generator 412b. Digital communication port 442 of source generator 412a and digital communication port 450 of bias generator 412b communicate via a digital communication link 457. Control signal port 460 of source generator 412a receives one or both of control signals 430, 430′. Output port 444 generates a control signal 458 input to input port 448. In various configurations, control signal 458 is substantially the same as the control signal controlling source generator 412a. In various other configurations, control signal 458 is the same as the control signal controlling source generator 412a, but is phase shifted within source generator 412a in accordance with a requested phase shift generated by bias generator 412b. Thus, in various configurations, source generator 412a and bias generator 412b are driven by substantially identical control signals or by substantially identical control signals phase shifted by a predetermined amount.

In various configurations, power supply system 410 may include multiple source generators 412a and multiple bias generators 412b. By way of nonlimiting example, a plurality of source generators 412a, 412a′, 412a″, . . . , 412a″ can be arranged to provide a plurality of output power signals to one or more source electrodes of load 432. Similarly, a plurality of bias generators 412b, 412b′, 412b″, . . . , 412b″ may provide a plurality of output power signals to a plurality of bias electrodes of load 432. When source generator 412a and bias generator 412b are configured to include a plurality of respective source generators or bias generators, each generator will output a separate signal to a corresponding plurality of matching networks 418a, 418b, configured to operate as described above, in a one-to-one correspondence. In various other configurations, there may not be a one-to-one correspondence between each generator and matching network. In various configurations, multiple source electrodes may refer to multiple electrodes that cooperate to define a composite source electrode. Similarly, multiple bias electrodes may refer to multiple connections to multiple electrodes that cooperate to define a composite bias electrode.

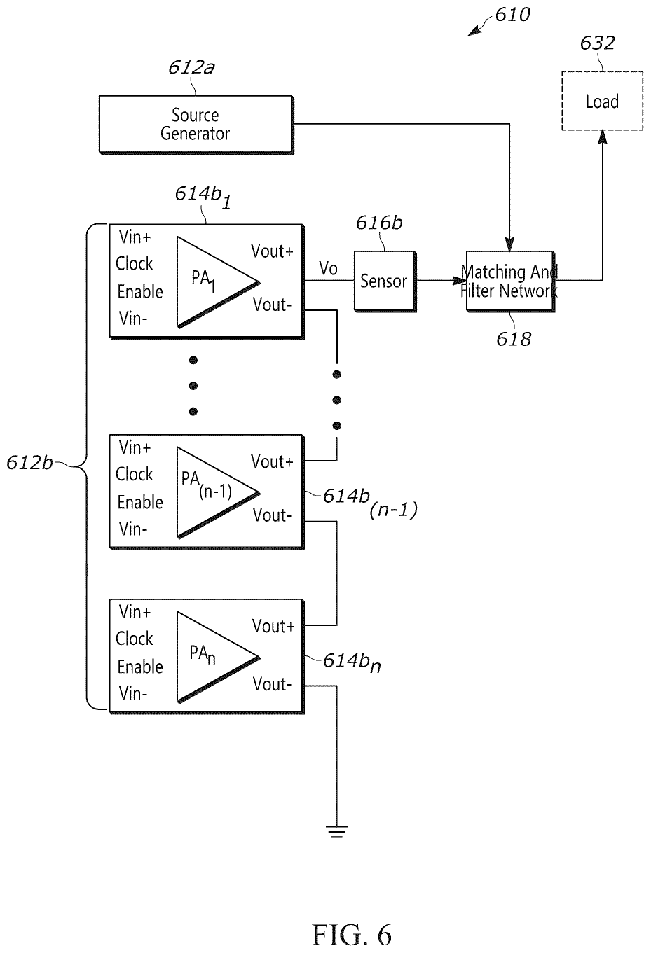

FIG. 5 depicts a plot of voltage versus time to describe a pulse or pulsed mode of operation for delivering voltage, current, or power to a load, such as load 432 of FIG. 4. More particularly, FIG. 5 depicts two multistate pulses P1, P2 of a pulse signal 512 having respective states S1-S4 and S1-S3. In FIG. 5, signal 510 is modulated by pulses P1 and P2, and, by way of nonlimiting example, is depicted as a RF sinusoidal signal or waveform. As shown at states S1-S3 of P1 and S1-S2 of P2, when the pulses are ON, RF generator 412 outputs signal 510 having an amplitude defined by the pulse magnitude at each state. Conversely, during states S4 of P1 and S3 of P2, the pulses are OFF, and generator 412 does not output signal 510. Pulses P1, P2 can repeat at a constant duty cycle or a variable duty cycle, and states S1-S4, S1-S3 of each respective pulse P1, P2 may have the same or varying amplitudes and widths.

In various configurations, signal 510 need not be implemented as a RF sinusoidal waveform as shown in FIG. 5. As referenced above with respect to FIG. 2, in addition to a sinusoidal waveform, in various configurations, signal 510 may be a nonsinusoidal waveform. By way of nonlimiting example, the RF signal 510 may be a rectangular waveform pulsed in a repeated or intermittent manner or a piecewise linear waveform as described in U.S. Pat. No. 10,396,601. In various configurations, pulse signal 512 may be other than a square wave as shown in FIG. 5. Further, by way of nonlimiting example, an envelope or pulse signal 512 may be a rectangular, trapezoidal, triangular, sawtooth, gaussian, or other shape that defines an envelope or modulating envelope of the underlying, modulated pulse signal 510. In various configurations, pulse signal 512 may occur or reoccur within fixed or variable periods or time periods. In various other configurations, pulse signal 510 may vary in shape between each occurrence. In various other configurations, pulse signal 510 may occur or reoccur within fixed or variable time periods and vary in shape between each occurrence. Further yet, pulses P1, P2 can have multiple states S1, . . . , Sn of varying amplitude, duration, and shape. States S1, . . . , Sn may repeat within fixed or variable periods and may include all or a portion of the various shapes described above. Also shown in FIG. 5, signal 510 may operate at frequencies that vary between states or within a state.

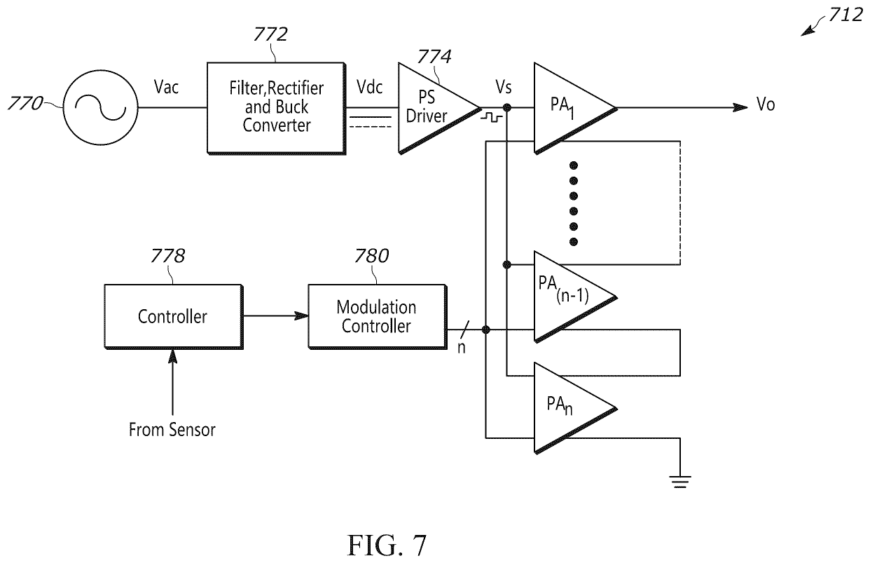

FIG. 6 shows an example power generation system 610. Although there are many applications for power generation system 610, one application implements a high aspect ratio (HAR) etching system. Power generation system 610 uses a pulsed DC bias generator having series-connected power amplifier modules. Power generation system 610 includes a source generator 612a and a bias generator 612b. Bias generator 612b includes a plurality, n in the nonlimiting example of FIG. 6, of power amplifier modules 614b₁, . . . , 614b₍ₙ₋₁₎, 614bₙ. Source generator 612a outputs a source signal to matching and filter network 618. Power amplifier modules 614b₁, . . . , 614b₍ₙ₋₁₎, 614bₙ of bias generator 614b are configured in series so that the series addition of the respective outputs defines a bias signal input to sensor 616b.

Source generator 612a shown in FIG. 6 represents a portion or the entirety of generator 412a of FIG. 4. Similarly, bias generator 612b shown in FIG. 6 represents a portion or the entirety of generator 412b of FIG. 4. Source generator 612a and bias generator 612b may include a power source 414, a sensor 416, and controller 420, not all of which may be shown in FIG. 6 and the following figures, but are shown in FIG. 4. Various control aspects implemented by controller 420 may be implemented via a standalone controller or be implemented via a common controller, such as controller 420′ of FIG. 4. Sensor 616b may be configured as a voltage/current sensor or a directional coupler as described above, depending upon the desired parameters to be measured. Sensor 616b of FIG. 6 represents a portion or the entirety of sensor 416b of FIG. 4. Sensor 616b passes the bias signal through to matching and filter network 618. In various configurations, matching and filter network 618 provides a matching function, as described above. In various configurations, matching and filter network 618 provides isolation between source generator 612a and bias generator 612b. In various configurations, matching and filter network 618 may be implemented as individual matching networks, such as matching network 418a and matching network 418b of FIG. 4. The output from matching and filter network 618 is input to load 632, which may be configured as a load as described above.

Power amplifier modules 614b₁, . . . , 614b₍ₙ₋₁₎, 614bₙ are configured in series so that the outputs of each power amplifier module 614b₁, . . . , 614b₍ₙ₋₁₎, 614bₙ are added in order to generate a combined output applied to sensor 616b. In various configurations, power amplifier modules 614b₁, . . . , 614b₍ₙ₋₁₎, 614bₙ are controlled via a common or individual controller (not shown in FIG. 6). In a common controller configuration, control may be provided by any one or combination of controllers, such as controllers 420a, 420b, or 420′ of FIG. 4. In various configurations, each power amplifier module 614b₁, . . . , 614b₍ₙ₋₁₎, 614bₙ includes a respective power amplifier PA₁, . . . , PA₍ₙ₋₁₎, PAₙ, and each respective power amplifier PA₁, . . . , PA₍ₙ₋₁₎, PAₙ outputs one of three output voltages, +V_{PA}, −V_{PA}, and 0 volts.

In various configurations, power amplifier modules 614b₁, . . . , 614b₍ₙ₋₁₎, 614bₙ receive respective positive supply voltage signal Vᵢₙ+ and negative supply voltage signal Vᵢₙ− that define a rail voltage, where Vᵢₙ− may be chassis or floating ground. The magnitude of the difference between the Vᵢₙ+ and Vᵢₙ− voltage signals determines the magnitude of the +V_{PA} and −V_{PA} output voltages. In various configurations, actuation of power amplifier modules 614b₁, . . . , 614b₍ₙ₋₁₎, 614bₙ is synchronized using a Clock signal, as shown in FIG. 6. In various configurations, the individual ones of power amplifier modules 614b₁, . . . , 614b₍ₙ₋₁₎, 614bₙ are actuated or deactuated and the voltage output by a respective power amplifier is determined by an Enable signal. The Enable signal determines whether a power amplifier PAₓ is actuated and also determines the output voltage, +V_{PA}, −V_{PA}, or 0 volts, of power amplifier PAₓ. In various configurations, the Enable signal, while shown as a single input to each amplifier module 614b₁, . . . , 614b₍ₙ₋₁₎, 614bₙ of FIG. 6, can represent a plurality of signals to control individual components of a respective power amplifier PAₓ. In various configurations, the Enable signal may be considered as drive signals for the individual components of power amplifier PAₓ, as will be described in greater detail herein.

In various configurations, for n power amplifier modules, the Clock signal synchronizes operation of the individual power amplifier modules 614b₁, . . . , 614b₍ₙ₋₁₎, 614bₙ, and the Enable signal determines which of the n power amplifier modules 614b₁, . . . , 614b₍ₙ₋₁₎, 614bₙ are actuated and the output voltage of each power amplifier module 614b₁, . . . , 614b₍ₙ₋₁₎, 614bₙ. The synchronization provided by the Clock signal provides for uniform transitions of the voltage signal to provide a output voltage Vo having pulse state changes with generally vertical transitions. If a predetermined number of power amplifier modules, m power amplifier modules for m less than n, by way of nonlimiting example, are actuated, the output of bias generator 612b may be a maximum voltage (m(+V_{PA})) and a minimum voltage (m(−V_{PA})). To achieve a maximum voltage output or minimum output voltage of bias generator 612b, all n power amplifier modules may be actuated to output a maximum voltage (n(+V_{PA})) or a minimum voltage (n(−V_{PA})).

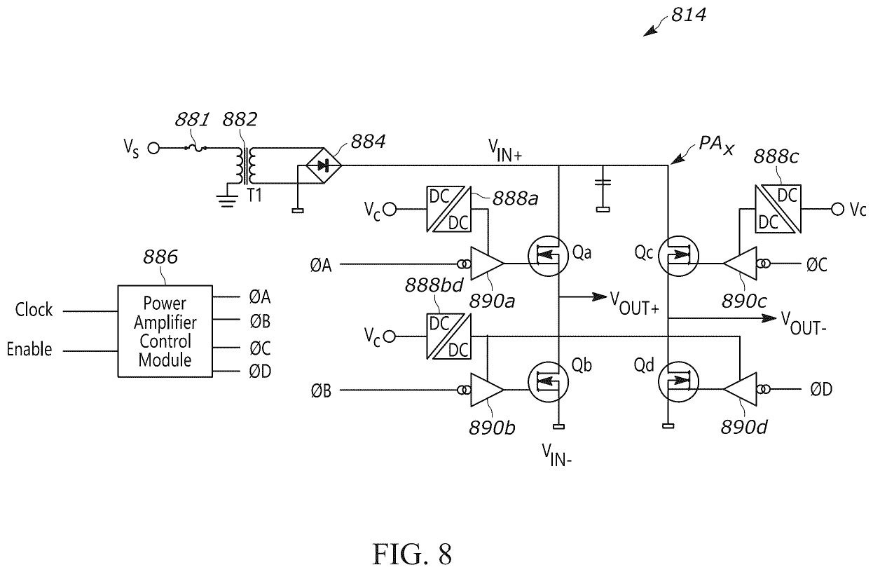

FIG. 7 shows a block diagram of a portion of bias generator 712, which represents an expanded block diagram of bias generator 612b of FIG. 6. AC power supply 770 outputs AC voltage signal Vac input to converter 772. In various configurations, AC voltage input to converter 772 is a three-phase AC voltage signal Vac and may be in the range of 396-528V AC, though any of a range of AC voltages may be input to converter 772. Converter 772 may be configured to include a filter network, AC/DC converter (such as a rectifier), and a buck converter and may be referred to as filter, rectifier and buck converter. In one configuration, the input AC voltage Vac is filtered for electromagnetic interference to smooth out the input AC voltage signal. The filtered AC voltage is input to a rectifier that converts the AC voltage to a DC voltage. The converted DC voltage is input to a buck converter, or step-down converter, that converts the DC voltage to a lower DC voltage, while optionally stepping up the current, to output supply voltage Vdc. In various configurations, filter elements of converter 772 may be omitted depending upon the input AC voltage signal from AC power supply 770. Likewise, in various configurations, the buck converter may be omitted from converter 772 depending upon the AC voltage signal input to converter 772 and the desired supply voltage Vdc output by converter 772.

Converter 772 outputs DC supply voltage Vdc to PS driver module 774. PS driver module 774 converts DC supply voltage Vdc to a voltage Vs, which may be a square wave voltage having a positive portion and a negative portion of equal magnitude. In various configurations, voltage Vs may be symmetric about 0 volts. Voltage Vs is input to each power amplifier PA₁, . . . , PA₍ₙ₋₁₎, PAₙ, and each power amplifier PA₁, . . . , PA₍ₙ₋₁₎, PAₙ is individually controlled by a the Enable signal to output one of voltages +V_{PA}, −V_{PA}, or 0 volts. The individual voltage outputs of power amplifier modules 614b₁, . . . , 614b₍ₙ₋₁₎, 614bₙ are synchronized by the Clock signal and combined in series to output a bipolar output voltage Vo shown in FIG. 7. Thus, the overall value of output voltage Vo depends upon the number of actuated power amplifiers PA₁, . . . , PA₍ₙ₋₁₎, PAₙ, the output of each power amplifier PA₁, . . . , PA₍ₙ₋₁₎, PAₙ (+V_{PA}, −V_{PA}, or 0 volts), and the supply voltage Vdc, which determines the amplitude of voltage Vs and in turn determines the magnitude of +V_{PA}, −V_{PA}, or 0 volts.

Bias generator 712 of FIG. 7 also includes a control section having controller 778 and modulation controller 780. Controller 778 receives feedback from a sensor, such as sensor 616b of FIG. 6. Controller 778 uses one or both of feedforward and feedback control to determine the supply voltage Vdc output by converter 772, the number of power amplifier modules 614b₁, . . . , 614b₍ₙ₋₁₎, 614bₙ to actuate, and the desired voltage (+V_{PA}, −V_{PA}, or 0 volts) output by each power amplifier module 614b₁, . . . , 614b₍ₙ₋₁₎, 614bₙ. Controller 778 communicates with converter 772 to control the buck converter of converter 772 in order to vary supply voltage Vdc. Controller 778 also communicates with modulation controller 780 to generate clock and Enable signals for controlling power amplifiers PA₁, . . . , PA₍ₙ₋₁₎, PAₙ of respective power amplifier modules 614b₁, . . . , 614b₍ₙ₋₁₎, 614bₙ. In various configurations, communication between controller 778 and converter 772 and modulation controller 780 occurs via electrical connection, optical connection, or wireless connection directly or using a bus and various communication protocols. Modulation controller 780 communicates with respective power amplifier modules 614b₁, . . . , 614b₍ₙ₋₁₎, 614bₙ to effect control of respective power amplifiers PA₁, . . . , PA₍ₙ₋₁₎, PAₙ. In various configurations, modulation controller 780 communicates at least one signal to each power amplifier module 614b₁, . . . , 614b₍ₙ₋₁₎, 614bₙ, so that if there are n power amplifier modules, modulation controller 780 communicates on n different signal paths to respective power amplifier modules 614b₁, . . . , 614b₍ₙ₋₁₎, 614bₙ. In various configurations, the signal paths can be separate bus connections or direct connections, including electrical, optical, or wireless connections. In various further configurations, modulation controller 780 uses n communication paths to communicate the Enable signal (which may be a plurality of command signals or drive signals for individual switches of each power amplifier PAₓ) and a common Clock communication path in which one output from modulation controller 780 connects to each of power amplifier modules 614b₁, . . . , 614b₍ₙ₋₁₎, 614bₙ. In various configurations, the Enable and Clock signals use RS-485 buses and drivers with fiber optic isolation.

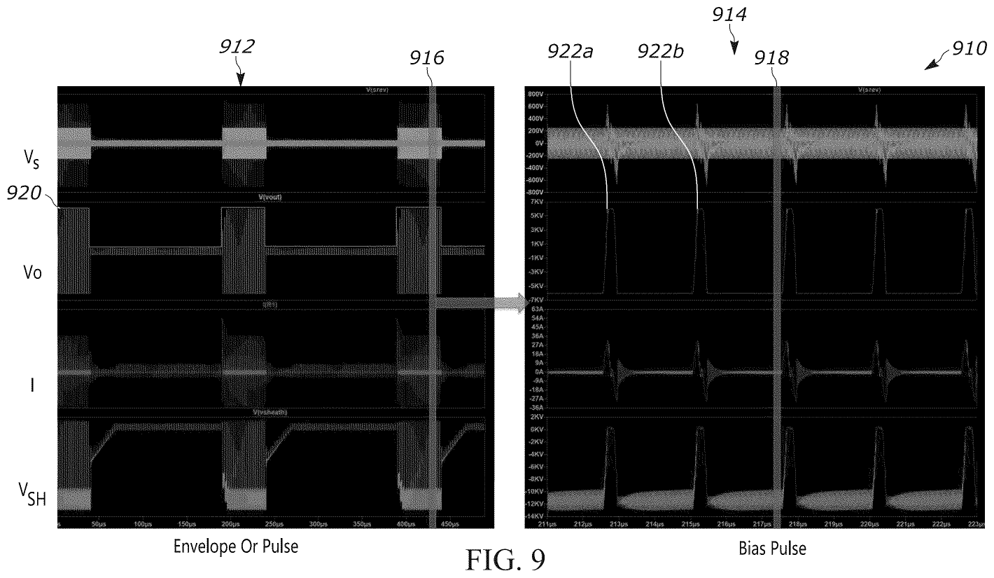

FIG. 8 shows a partial schematic block diagram of a power amplifier module 814, which may represent any of power amplifier modules 614b₁, . . . , 614b₍ₙ₋₁₎, 614bₙ described herein. Power amplifier module 814 includes power amplifier PAₓ having a plurality of switches Qa, Qb, Qc, Qd arranged in a full bridge configuration, though it should be recognized that power amplifier PAₓ may be configured using other power amplifier configurations, such as a half-bridge. Voltage Vs provides a fixed supply voltage relative to chassis ground to power amplifier module 814, and is applied to transformer 882 via fusible link 881. Transformer 882 (T1) provides isolation between converter and power supply driver, such as converter 772 and PS driver module 774 of FIG. 7, and power amplifier module 814. The output of transformer 882 is input to rectifier 884 which converts voltage Vs to a DC voltage Vᵢₙ+. In the configuration of FIG. 8, one terminal of rectifier 884 connects to chassis ground so that the fixed supply voltage of voltage Vs is converted to a floating voltage, Vᵢₙ−. Thus, Vᵢₙ+ and Vᵢₙ− define a rail voltage for switches Qa, Qb, Qc, Qd of power amplifier PAₓ.

Power amplifier module 814 also includes power amplifier control module 886. Power amplifier control module 886 receives a Clock signal and an Enable signal (or signals) that power amplifier control module 886 processes to determine the operation of switches Qa, Qb, Qc, Qd of power amplifier PAₓ. Power amplifier control module 886 receives Clock and Enable signals and decodes the signals into drive signals ϕa, ϕb, ϕc, ϕd applied to the gates of respective switches Qa, Qb, Qc, Qd to control actuation of each switch. In various configurations, drive signals ϕa, ϕb, ϕc, ϕd may be applied directly to the gates of respective switches Qa, Qb, Qc, Qd. In various other configurations, ϕa, ϕb, ϕc, ϕd are applied to respective gate drive buffers or gate drive amplifier 890a, 890b, 890c, 890d. Gate drive amplifier 890a is powered by a DC/DC converter 888a, and gate drive amplifier 890c is powered by a DC/DC converter 888c. Gate drive amplifier 890b and gate drive amplifier 890d are powered by a single DC/DC converter 888bd. Each DC/DC converter 888a, 888c, 888bd receives an input voltage Vc. Each DC/DC converter and associated gate drive amplifier provides a floating voltage supply to operate respective switches Qa, Qb, Qc, Qd in accordance with drive signals ϕa, ϕb, ϕc, ϕd.

As described above, power amplifiers 614b₁, . . . , 614b₍ₙ₋₁₎, 614bₙ output one of +V_{PA}, −V_{PA}, or 0 volts. The output voltage V_{PA}_{ₓ} of power amplifier PAₓ can be defines as in Equation (1):

$${V}_{{PA}_{x}} = {V}_{{out}^{+}} - {V}_{{out}^{-}} \qquad ( 1 )$$

With reference to power amplifier PAₓ of power amplifier module 814, Equations (2), (3), and (4) define the output voltage V_{PA}_{ₓ}:

$${V}_{{PA}_{x}} = + {V}_{PA} when Qa and Qd = ON \qquad ( 2 )$$

$${V}_{{PA}_{x}} = - {V}_{PA} when Qc and Qd = ON \qquad ( 3 )$$

$${V}_{{PA}_{x}} = 0 v when Qa and Qc = ON or Qb and Qd = ON \qquad ( 4 )$$

Further, power amplifier modules 614b₁, . . . , 614b₍ₙ₋₁₎, 614bₙ are arranged in series by connecting a Vₒᵤₜ+ terminal of one power amplifier module to a Vₒᵤₜ− terminal of a succeeding power amplifier module. One Vₒᵤₜ− terminal of the group of power amplifier modules 614b₁, . . . , 614b₍ₙ₋₁₎, 614bₙ connects to ground, and one Vₒᵤₜ+ terminal of the group of power amplifier modules 614b₁, . . . , 614b₍ₙ₋₁₎, 614bₙ connects to bias generator output Vo.

Power amplifier module 814 has been described herein as having power amplifier control module 886 associated with each power amplifier module 814. In various configurations, each power amplifier module 614b₁, . . . , 614b₍ₙ₋₁₎, 614bₙ may have a similar arrangement. However, as described above, control provided by power amplifier control module 886 can be distributed between controller or power amplifier control module 886 and modulation controller 780 of FIG. 7 or controllers 420a, 420b, or 420′. Thus, in some configurations, controller or power amplifier control module 886 and modulation controller 780 of FIG. 7 or controllers 420a, 420b, or 420′ may be configured to generate drive signals ϕa, ϕb, ϕc, ϕd in accordance with a common clock directly to respective switches Qa, Qb, Qc, Qd. In such a configuration, power amplifier module 814 may be a conventionally configured power amplifier controlled in accordance with the principles of the present disclosure.

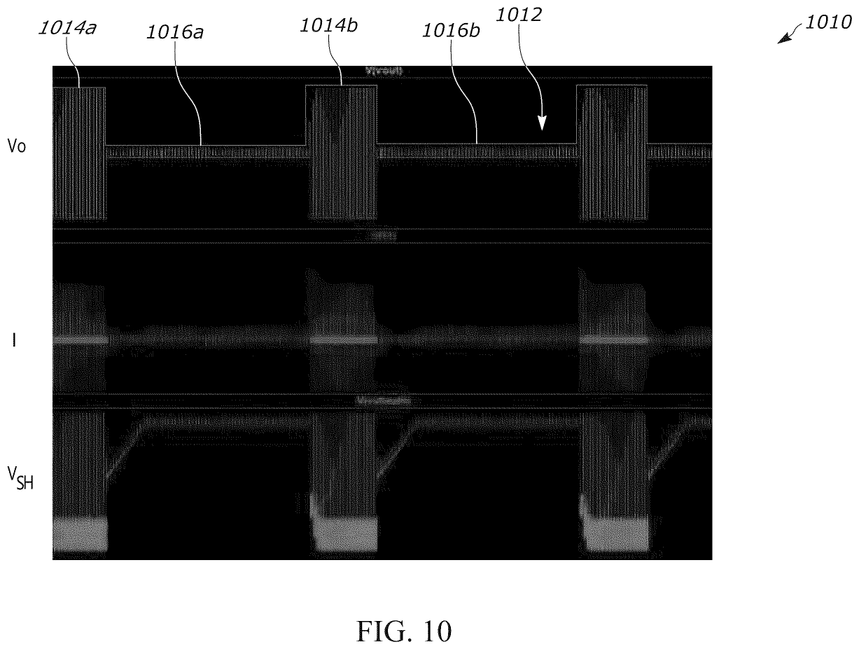

FIG. 9 shows waveforms 910 for describing voltage control using a nested sample and hold approach for controlling to output voltage Vo and the feedback signals input to various controllers for controlling operation of the power amplifiers of the power amplifier modules. Waveforms 910 include first view 912 and second view 914. Second view 914 is an expanded view of a slice of first view 912 taken at time slice 916. Waveforms 910 show voltage Vs as shown in FIGS. 7 and 8, Vo as shown in FIG. 7, current I as measured by sensor 616b of FIG. 6 or sensor 416b of FIG. 4, and sheath voltage V_{SH} as will be described further herein.

FIG. 9 is used to describe a sampling approach including a first holdoff and a second holdoff for sampling so that sampling of the output voltage Vo occurs at an optimal position within a pulse or envelope and an optimal position within a carrier signal modulated by the pulse or envelope. In various configurations, a modulation envelope or pulse 920 defines a shape of output voltage or waveform Vo shown in first view 912. Time slice 916 may be selected in accordance with where to sample the desired parameter of interest. By way of nonlimiting example, a first sampling position or holdoff time may be determined based on where sufficient time has passed from a positive-going edge (or negative-going edge) of envelope or pulse 920 to allow settling of one or more parameter to be measured or the output voltage or waveform Vo.

Second view 914 shows individual cycles or pulses 922a, 922b of the output voltage or waveform Vo. Time slice 918 in second view 914 determines where to sample the desired parameter of interest in cycles or pulses 922a, 922b of output voltage or waveform Vo. A second sampling position or second holdoff time is determined relative to a positive-going or negative-going transition of cycles or pulses 922a, 922b. By way of nonlimiting example, the sampling position or the second holdoff may be determined based on where sufficient time has passed from a positive-going edge (or negative-going edge) of cycles or pulses 922a, 922b to allow settling of the parameter to be measured. It should be noted that with respect to etching high aspect ratio features, it is during the negative portions of the cycles or pulses 922a, 922b (approximately −6000 kV in second view 914) during which the etching of high aspect ratio features occurs. Further, it is during the positive portions of cycles or pulses 922a, 922b during which processes such as low energy polymer formation occur.

In various configurations, the controllers described herein can use a combination of feedback, feedforward, or MIMO (Multiple Input, Multiple Output) control schemes to control the DC voltage Vdc output by converter 772 and the number of power amplifiers PA₁, . . . , PA₍ₙ₋₁₎, PAₙ of FIG. 7 (or power amplifier modules 614b₁, . . . , 614b₍ₙ₋₁₎, 614bₙ of FIG. 6) to be actuated. Further, other control schemes can be implemented using the configuration of the various bias generators described herein. By way of nonlimiting example, the plasma sheath potential, V_{SH} of FIG. 9, can be measured or estimated and fed back to the controllers described herein. In addition, the apparent ion potential could be estimated as a feedback parameter. Examples of various approaches to determining the sheath potential can be found with reference to U.S. patent application Ser. No. 17/884,711, filed Aug. 10, 2022, entitled Plasma Process Control of Multi-Electrode Systems Equipped with Ion Energy Sensors; and U.S. patent application Ser. No. 18/158,164, filed Jan. 23, 2023, entitled Non-Invasive IED Estimation for Pulsed-DC and Low Frequency Applications, both assigned to the assignee of the present application and incorporated by reference in this application.

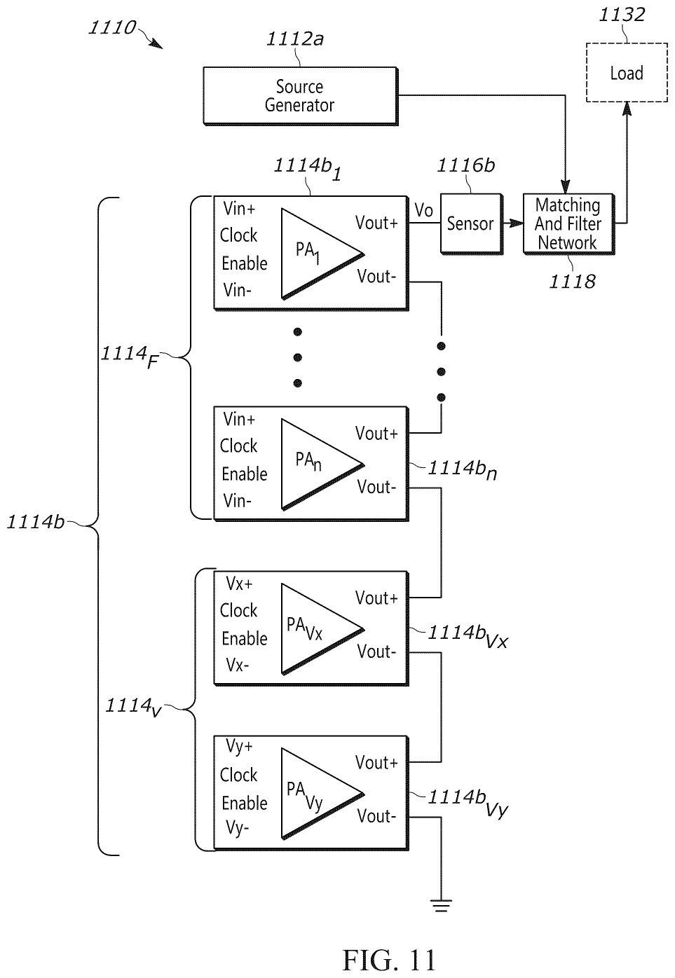

FIG. 10 shows waveforms 1010 similar to waveforms of first view 912 of FIG. 9 in order to describe multistate pulse modulation. Multistate pulse modulation is described generally above with respect to FIG. 5 and is equally applicable to the description of FIG. 10. In FIG. 10, output voltage or waveform Vo shows multistate pulse or envelope 1012 for output voltage or waveform Vo. Multistate pulse or envelope 1012 includes first state 1014a and second state 1016a. Multistate pulse or envelope 1012 also includes first state 1014b and a second state 1016b. Each first state 1014a and first state 1014b can have different and varying time periods and different and varying amplitudes. Similarly, each second state 1016a and second state 1016b can have different and varying time periods and different and varying amplitudes.

Present semiconductor etch and deposition processes call for bias generators that can produce complex amplitude modulation envelopes, such as the multistate pulsing described with respect to FIG. 10. In a nonlimiting example of FIG. 10, rectangular multistate pulse or envelope 1012 has a 10 kHz pulse repetition rate and 25% duty cycle. High voltage pulse first states 1014a, 1014b have an amplitude of approximately 13 kV peak-to-peak. Low voltage pulse second states 1016a, 1016b have an amplitude of approximately 1 kV. As mentioned above, the low voltage state is typically used for ion-assisted etching of materials such as silicon dioxide or silicon nitride. The high voltage state can be used to promote polymer formation for sidewall protection and improved etch profile control. As described above with respect to FIG. 5, pulse states may vary in amplitude, frequency, and duty cycle.

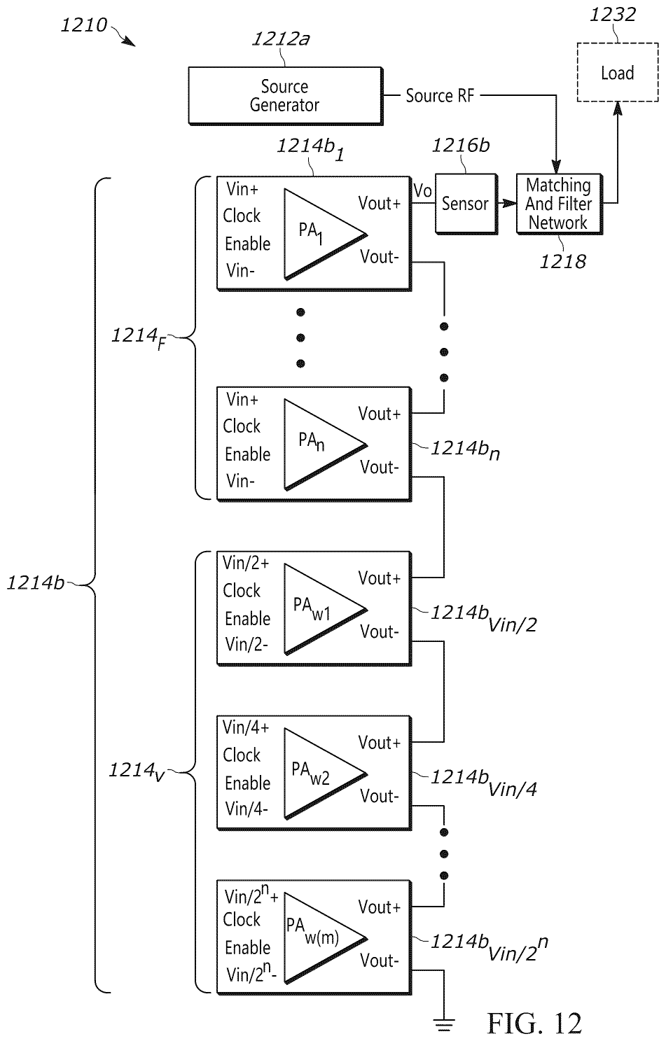

To control the amplitude of multistate pulses, additional power amplifier modules that have a different supply voltage than the fixed step power amplifier modules 614b₁, . . . , 614b₍ₙ₋₁₎, 614bₙ of FIG. 6 (or power amplifiers PA₁, . . . , PA₍ₙ₋₁₎, PAₙ of FIG. 7) can be inserted into the series connection of power amplifiers. Additional power amplifier modules can be configured to enable the generation of an output voltage Vo intermediate to the fixed step multiples of V_{PA}_{ₓ}. FIG. 11 shows an example power generation system 1110 including source generator 1112a, bias generator 1114b, sensor 1116b, matching and filter network 1118, and load 1132, all of which operate similarly to the generator, bias generator, sensor, matching and filter network, and load described above and further described herein. In the configuration of FIG. 11, bias generator 1114b includes a fixed step generation section 1114_{F} and a variable step generation section 1114y. Fixed step generation section 1114_{F} includes power amplifier modules 1114b₁, . . . , 1114b₍ₙ₋₁₎, 1114bₙ, with power amplifier module 1114b₍ₙ₋₁₎ not shown in FIG. 11, but it will be understood that power amplifier module 1114b₍ₙ₋₁₎ is included in the series connection. As described above with respect to power amplifier modules 614b₁, . . . , 614b₍ₙ₋₁₎, 614bₙ and (power amplifiers PA₁, . . . , PA₍ₙ₋₁₎, PAₙ), power amplifier modules 1114b₁, . . . , 1114b₍ₙ₋₁₎, 1114bₙ are arranged to output one of three voltages +V_{PA}, −V_{PA}, or 0. As also described above, voltages +V_{PA}, −V_{PA}, or 0 volts vary in accordance with supply voltage Vdc, which determines voltage Vs, which in turn determines rail voltages Vᵢₙ+/Vᵢₙ− (where Vᵢₙ− connects to chassis ground in various configurations described herein).

Variable step generation section 1114_{V} includes one or a plurality of power amplifier modules 1114b_{Vx} and 1114b_{Vy}, which include respective power amplifiers PA_{Vx} and PA_{Vy}. While only two power amplifier modules 1114b_{Vx} and 1114b_{Vy} are shown in FIG. 11, it should be understood that the referenced plurality can include more than two power amplifier modules 1114b_{Vx} and 1114b_{Vy}. Power amplifier modules 1114b_{Vx} and 1114b_{V} are driven at respective rail voltages Vₓ+/Vₓ− and V_{y}+/V_{y}−, which differ from rail voltages Vᵢₙ+/Vᵢₙ− applied to power amplifier modules 1114b₁, . . . , 1114b₍ₙ₋₁₎, 1114bₙ. Thus, power amplifier module 1114b_{Vx} outputs one of voltages +V_{PAx}, −V_{PAx}, or 0, depending upon the actuation of its switches Qa, Qb, Qc, Qd. Similarly, power amplifier module 1114b_{Vy} outputs one of voltages +V_{Pay}, −V_{Pay}, or 0, depending upon the actuation of its switches Qa, Qb, Qc, Qd. Rail voltages Vₓ+/Vₓ− and V_{y}+/V_{y}− may be generated by a filter, rectifier and buck converter and PS driver pair, such as filter, rectifier and buck converter of converter 772 and PS driver module 774 of FIG. 7, configured to output different respective supply voltage Vdc and voltage Vs.

By way of nonlimiting example, in a first pulse state (state1), power amplifier modules 1114b_{Vx} and 1114b_{Vy} are disabled, and the output voltage is determined by the number of fixed step modules enabled, the drive signals that determine the output voltages +V_{PA}, −V_{PA}, or 0 volts, and supply voltage Vdc. In a second pulse state (state 2), power amplifier module 1114b_{Vx} can be enabled to add a first variable voltage that differs from the voltage output by each of power amplifier modules 1114b₁, . . . , 1114b₍ₙ₋₁₎, 1114bₙ. In a third pulse (state 3), power amplifier module 1114b_{Vx} can be disabled and power amplifier module 1114b_{Vy} can be enabled to add a second variable voltage that differs from the voltage output by each of power amplifier modules 1114b₁, . . . , 1114b₍ₙ₋₁₎, 1114bₙ and from the voltage output by power amplifier module 1114b_{Vx}. Power amplifier modules 1114b₁, . . . , 1114b₍ₙ₋₁₎, 1114bₙ can also be added as needed to further control the output voltage of state2 and state3.

More states can be added as required by actuating an appropriate number of power amplifier modules 1114b₁, . . . , 1114b₍ₙ₋₁₎, 1114bₙ of fixed step generation section 1114_{F} and power amplifier modules of variable step generation section 1114_{V}. While only two power amplifier modules 1114b_{Vx} and 1114b_{Vy} are shown in fixed step generation section 1114_{F}, fixed step generation section 1114_{F} can include one or a plurality of power amplifier modules. Further, a first plurality of power amplifier modules of fixed step generation section 1114_{F} may be configured to generate the same output voltage, and a second plurality of power amplifier modules of fixed step generation section 1114_{F} may be configured to generate the same output voltage, where the output voltage of the power amplifier modules of the first plurality differs from the output voltage of the power amplifier modules of the second plurality.

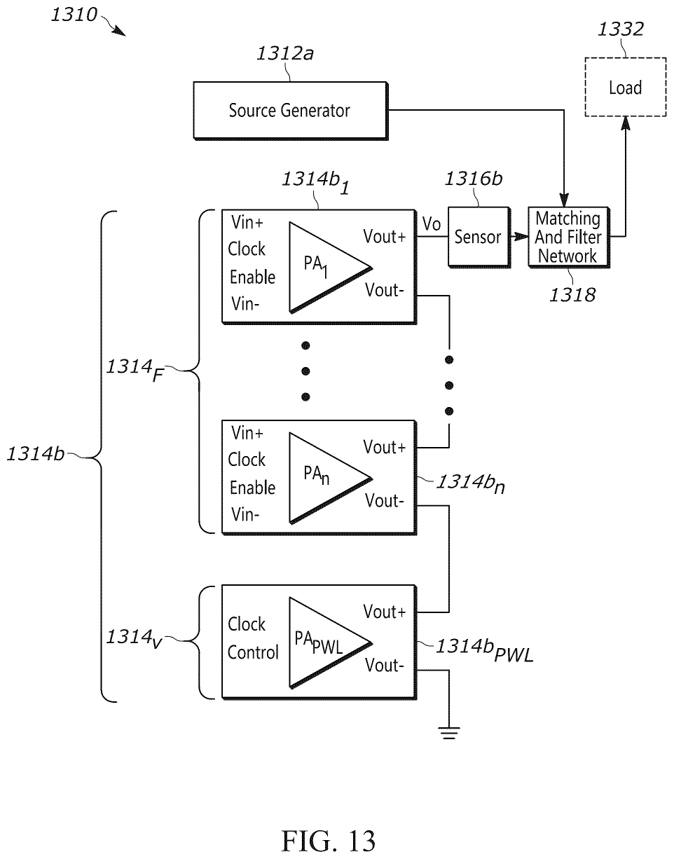

FIG. 12 shows an example power generation system 1210 including source generator 1212a, bias generator 1214b, sensor 1216b, matching and filter network 1218, and load 1232, all of which operate similarly to the generator, bias generator, sensor, matching and filter network, and load described above and further described herein. In the configuration of FIG. 12, bias generator 1214b includes a fixed step generation section 1214_{F} and a variable step generation section 1214_{V}. Fixed step generation section 1214_{F} includes power amplifier modules 1214b₁, . . . , 1214b₍ₙ₋₁₎, 1214bₙ, with power amplifier module 1214b₍ₙ₋₁₎ not shown in FIG. 12, but it will be understood that power amplifier module 1214b₍ₙ₋₁₎ is included in the series connection. As described above with respect to power amplifier modules 614b₁, . . . , 614b₍ₙ₋₁₎, 614bₙ (or power amplifiers PA₁, . . . , PA₍ₙ₋₁₎, PA, of FIG. 7), power amplifier modules 1214b₁, . . . , 1214b₍ₙ₋₁₎, 1214bₙ are arranged to output one of three voltages +V_{PA}, −V_{PA}, or 0. As described above, voltages +V_{PA}, −V_{PA}, or 0 volts vary in accordance with supply voltage Vdc, which determines voltage Vs, which in turn determines rail voltages Vᵢₙ+/Vᵢₙ− (where Vᵢₙ− connects to chassis ground in various configurations described herein).

Variable step generation section 1214_{V} includes one or a plurality of power amplifier modules 1214b_{Vin/2}, 1214b_{Vin/4}, . . . , 1214b_{Vin/2}_{ⁿ}, which include respective power amplifiers PA_{W1}, PA_{W2}, PA_{W(m-1)} (not shown), . . . . PA_{W(m)}. In the configuration of FIG. 12, power amplifier modules 1214b_{Vin/2}, 1214b_{Vin/4}, and 1214b_{Vin/2}_{ⁿ}. are configured to operate at respective rail voltages +Vin/2, −Vin/2; +Vin/4, −Vin/4; . . . ; +Vin/2ⁿ, −Vin/2ⁿ, which are binary fractions of rail voltages Vᵢₙ+/Vᵢₙ− applied to power amplifier modules 1214b₁, . . . , 1214b₍ₙ₋₁₎, 1214bₙ in order to generate binary steps of +V_{PA} and −V_{PA} voltages output by power amplifier modules 1214b₁, . . . , 1214b₍ₙ₋₁₎, 1214bₙ. Thus, power amplifier module 1214b_{Vin/2}, outputs one of voltages +V_{PAx}/2, −V_{PAx}/2, or 0, depending upon the actuation of its switches Qa, Qb, Qc, Qd. Similarly, power amplifier module 1214b_{Vin/2} outputs one of voltages +V_{PAx}/4, −V_{PAx}/4, or 0, depending upon the actuation of its switches Qa, Qb, Qc, Qd. Similarly yet, power amplifier module 1214b_{Vin/2}_{ⁿ} outputs one voltages +V_{PAx}/2ⁿ, −V_{PAx}/2ⁿ, or 0, depending upon the actuation of its switches Qa, Qb, Qc, Qd. Rail voltages +Vin/2, −Vin/2; +Vin/4, −Vin/4; . . . ; +Vin/2ⁿ, −Vin/2ⁿ may be generated by individual filter, rectifier and buck converter and PS driver pairs, such as filter, rectifier and buck converter of converter 772 and PS driver module 774 of FIG. 7, configured to output different respective supply voltage Vdc and alternating current voltage Vs. The binary implementation of variable step generation section 1214_{V} is described in U.S. Patent Application No. 63/441,616, filed on Jan. 27, 2023, entitled Pulsed RF Plasma Generator With High Dynamic Range, assigned to the assignee of the present application, and incorporated by reference herein.

The power generation system 1210 of FIG. 12 can be operated similarly to the power generation systems described above having a fixed step generation section and a variable step generation section. Bias generator 1214b of power generation system 1210 may be controlled as described above with respect to FIG. 11, with the variable steps being binary, variable steps of voltages +V_{PA} and −V_{PA}.

With reference to FIGS. 8 and 11-13, transformer 882 can be configured to provide a voltage step down between a primary winding receiving Vs and a secondary winding generating an output voltage to rectifier 884. Thus, in addition to providing isolation between the circuitry generating Vs, such as converter 772 and PS driver module 774, transformer 882 can provide voltage control of the input voltage applied to transform 882. In various configurations, transformer 882 can be configured to provide a voltage step up between a primary winding receiving Vs and a secondary winding generating an output voltage to rectifier 884.

By way of nonlimiting example, with reference to FIG. 11, one or more of rail voltages or voltages Vᵢₙ+/Vᵢₙ−, Vₓ+/Vₓ−, V_{y}+/V_{y}− may be generated based upon voltage Vs output by PS driver module 774 and input to respective power amplifiers PA₁, . . . , PA₍ₙ₋₁₎, PA_{Vx}, PA_{Vy}. By varying a ratio of turns between respective primary and secondary coils of 882, voltage Vs input to respective power amplifiers PA₁, . . . , PA₍ₙ₋₁₎, PA_{Vx}, PA_{Vy} may be correspondingly varied. As referenced above with respect to FIG. 11, rail voltages or voltages Vᵢₙ+/Vᵢₙ−, Vₓ+/Vₓ−, V_{y}+/V_{y}− may be generated by a filter, rectifier and buck converter and PS driver pair, such as filter, rectifier and buck converter of converter 772 and PS driver module 774 of FIG. 7, configured to output different respective supply voltages Vdc and resulting voltage Vs. Further, in various configurations, a first of the above-described approaches for generating voltage Vs may be used for generating voltage Vs input to a first power amplifier module and in the other of the above-described approaches for generating voltage Vs may be used for generating voltage Vs input to a second power amplifier module.

Similarly, and by way of nonlimiting example, with reference to FIG. 12, one or more of rail voltages or voltages Vᵢₙ+, Vᵢₙ−; +Vin/2, −Vin/2; +Vin/4, −Vin/4; . . . ; +Vin/2ⁿ, −Vin/2ⁿ may be generated based upon voltage Vs output by PS driver module 774 and input to respective power amplifiers PA₁, . . . , PA₍ₙ₋₁₎, PA_{W1}, PA_{W2}, PA_{W(m-1)}, PA_{W(m)}. By varying a ratio of turns between respective primary and secondary coils of 882, voltage Vs input to respective power amplifiers PA₁, . . . , PA₍ₙ₋₁₎, PA_{W1}, PA_{W2}, PA_{W(m-1)}, and PA_{W(m)} may be correspondingly varied. As described above with respect to FIG. 12, voltages +Vin/2, −Vin/2; +Vin/4, −Vin/4; . . . ; +Vin/2ⁿ, −Vin/2ⁿ may be generated by individual filter, rectifier and buck converter and PS driver pairs, such as filter, rectifier and buck converter of converter 772 and PS driver module 774 of FIG. 7, configured to output different respective supply voltage Vdc and current voltage Vs. Further, in various configurations, a first of the above-described approaches for generating voltage Vs may be used for generating voltage Vs input to a first power amplifier module and an other of the above-described approaches for generating voltage Vs may be used for generating voltage Vs input to a second power amplifier module.

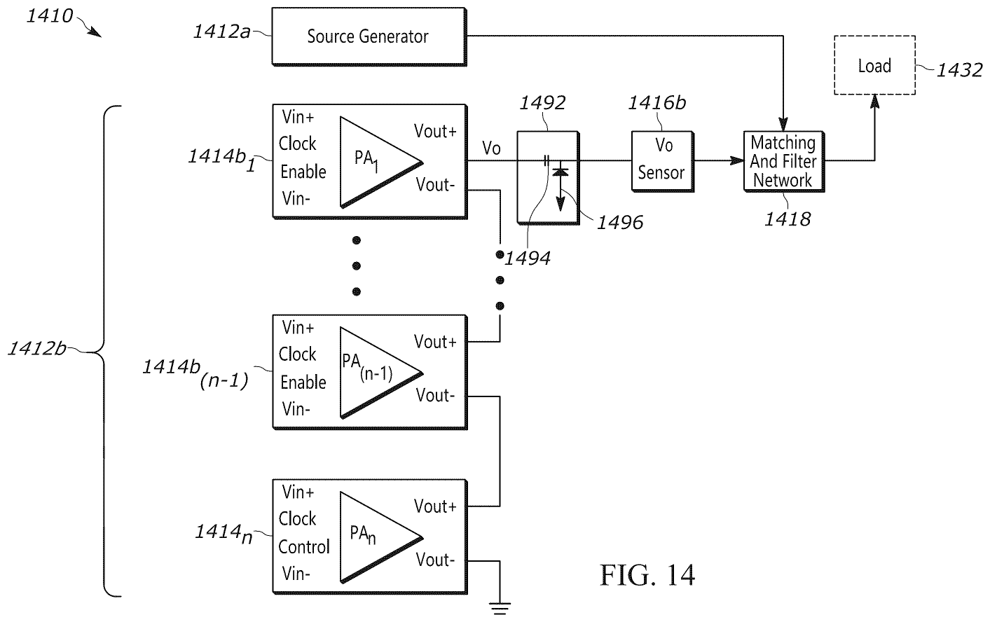

FIG. 13 shows an example power generation system 1310 including source generator 1312a, bias generator 1314b, sensor 1316b, matching and filter network 1318, and load 1332, all of which operate similarly to the generator, bias generator, sensor, matching and filter network, and load described above and further described herein. In the configuration of FIG. 13, bias generator 1314b includes a fixed step generation section 1314; and a variable step generation section 1314_{V}. As described above with respect to power amplifier modules 614b₁, . . . , 614b₍ₙ₋₁₎, 614bₙ (and power amplifiers PA₁, . . . , PA₍ₙ₋₁₎, PAₙ of FIG. 7), power amplifier modules 1314b₁, . . . , 1314b₍ₙ₋₁₎, 1314bₙ are arranged to output one of three voltages +V_{PA}, −V_{PA}, or 0. Fixed step generation section 1314; includes power amplifier modules 1314b₁, . . . , 1314b₍ₙ₋₁₎, 1314bₙ, with power amplifier module 1314b₍ₙ₋₁₎ not shown in FIG. 13, but it will be understood that power amplifier module 1314b₍ₙ₋₁₎ is included in the series connection. Power amplifier modules 1314b₁, . . . , 1314b₍ₙ₋₁₎, 1314bₙ are arranged to output one of three voltages +V_{PA}, −V_{PA}, or 0. As described above, voltages +V_{PA}, −V_{PA}, or 0 volts vary in accordance with drive voltage Vdc, which determines voltage Vs, which in turn determines rail voltages Vᵢₙ+/Vᵢₙ− (where Vᵢₙ− connects to chassis ground in the various configurations described herein).

Variable step generation section 1314_{V} includes power amplifier module 1314b_{PWL}, having a power amplifier PA_{PWL}. In the configuration of FIG. 13, power amplifier module 1314b_{PWL} is configured to output a piecewise linear voltage waveform. The piecewise linear voltage waveform can be rapidly adjusted to shape the bias waveform output by fixed step generation section 1314_{F}. Power generation system 1310 of FIG. 13 can be operated similarly to the power generation systems described above having a fixed step generation section and a variable step generation section. Bias generator 1314b of power generation system 1310 may be controlled as described above, with the variable steps being determined on a piecewise linear basis. It should be noted that the output of power amplifier module 1314b_{PWL} allows generation of ramp signal using DC amplifiers and its output should be considered a DC signal in the present disclosure. A description of operation of piecewise linear power amplifier module 1314b_{PWL} can be found, by way of nonlimiting example, in U.S. Pat. No. 10,396,601, referenced herein.

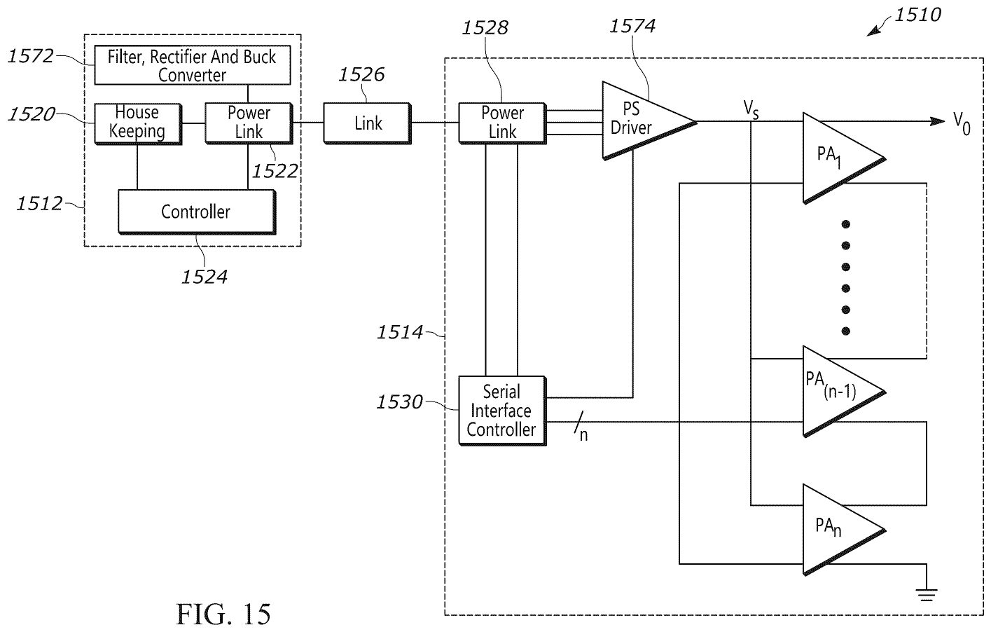

FIG. 14 shows an example power generation system 1410 including source generator 1412a, bias generator 1414b, sensor 1416b, matching and filter network 1418, and load 1432, all of which operate similarly to the generator, bias generator, sensor, matching and filter network, and load described above and further described herein. In the configuration of FIG. 14, bias generator 1414b may include a fixed step generation section 1414b₁, . . . , 1414b₍ₙ₋₁₎, 1414bₙ and a variable step generation section (not shown). FIG. 14 is configured so that the output voltage Vo is a unipolar voltage, as compared to a bipolar voltage output by the power generation systems described above. FIG. 14 includes a DC charge pump 1492 that transitions the bipolar voltage Vo output by bias generator to a unipolar voltage input to sensor 1416b. DC charge pump 1492 includes a capacitor 1494 arranged in series between power generation module 1414b₁ and sensor 1416b, and a diode 1496 having a cathode connected between capacitor 1494 and sensor 1416b and an anode connected to ground. Diode 1496 may be referred to as a stealing diode. The arrangement of diode 1496 provides a positive unipolar output voltage Vo. If the configuration of diode 1496 is reversed so that its anode connects between capacitor 1494 and sensor 1416b and cathode connects to ground, the unipolar output will be negative.

In the power generation systems described herein where the DC square wave output Vo transitions between a first and second voltage, it is generally desirable that the transitions occur relatively quickly. When delivering a DC square wave to a mismatched load, reflections from the load occur can occur, which appear as ringing. Thus, the fast edges required for the pulsed bias applications described herein can result in significant waveform distortion and ringing. One approach to mitigating ringing is to significantly reduce the length of the output cable between the bias generator and the electrostatic chuck/wafer in the load. This can be achieved with a dual-box design that places the AC front-end, power supplies, and controller in a rack-mount chassis remote to the power amplifier modules, and power deliver switching components in proximity to the load. A high speed communication link can be used to collect feedback and control the PA actuators.

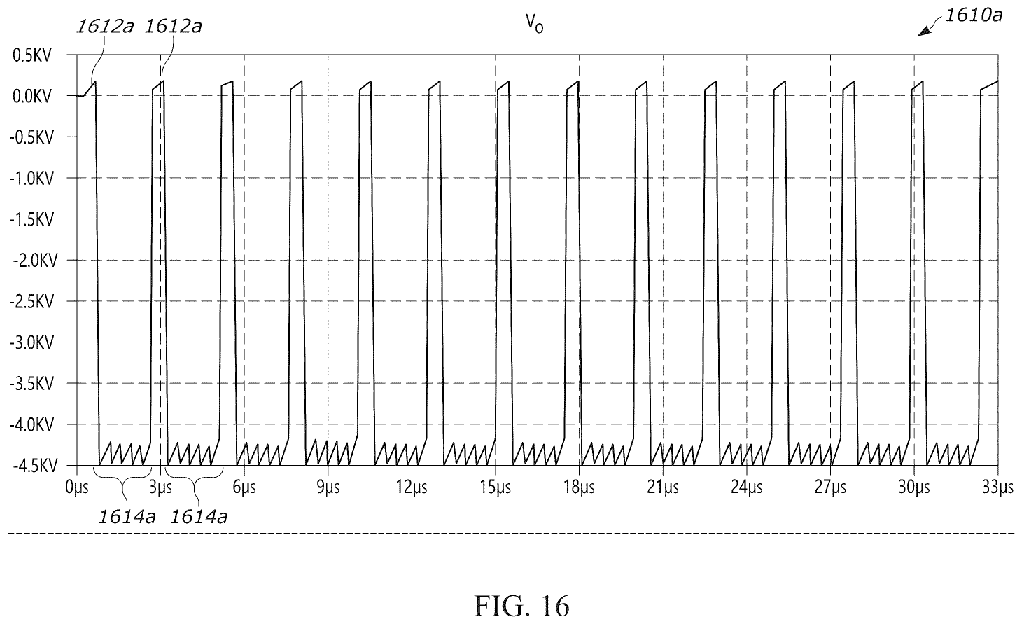

FIG. 15 shows an example power generation system 1510 arranged to reduce waveform distortion and ringing by placing power amplifier modules in proximity to the load and placing AC front end, power supplies, and controllers remote from the load. The configuration of FIG. 15 provides an additional benefit of reducing space requirements for the power generation system 1510 on the fabrication floor. In various configurations, power amplifier modules placed in proximity to the load require less space than the AC front end, power supplies, and controllers place remote from the load.

FIG. 15 includes a remote module 1512 and a proximity module 1514 of power generation system 1510. Remote module 1512 is placed remotely from the load, typically in a location remote from semiconductor fabrication floor space, which is generally considered expensive space. Proximity module 1514, on the other hand, is placed in close proximity to the load so that the cable length between the power amplifier modules, shown as PA₁, . . . , PA₍ₙ₋₁₎, PAₙ, can be made substantially shorter than in a conventional power generation configuration. Remote module 1512 includes filter, rectifier and buck converter 1572, housekeeping module 1520, power link 1522, and controller 1524. Filter, rectifier and buck converter 1572 operates as described above to generate a voltage signal Vdc. Housekeeping module 1520 manages housekeeping functions for power generation system 1510. The housekeeping functions can generally be described as control functions not directly related to the delivery of power. Controller 1524 manages operation of remote module 1512, including providing control signals to filter, rectifier and buck converter 1572, either directly or indirectly. Power link 1522 receives DC voltage Vdc from filter, rectifier and buck converter 1572. Power link 1522 also receives control signals from controller 1524. Power link 1522 communicates with power link 1528 of proximity module 1514. A link 1526 communicates power, data, and sensor signals between power link 1522 and power link 1528.

Control and data signals are communicated to proximity module 1514 via power link 1528. Proximity module 1514 includes PS driver 1574, which operates similarly to PS driver module 774 of FIG. 7. Proximity module 1514 also includes serial interface controller 1530, which operates similarly to modulation controller 780. Modulation controller 780 receives data and control signals via power link 1528 and generates Clock and Enable signals to respective power amplifier modules PA₁, . . . , PA₍ₙ₋₁₎, PAₙ. From the configuration of power generation system 1510 of FIG. 15, it can be seen that the switching components are desirably placed in proximity to the load, while other components can be placed remote from the load.

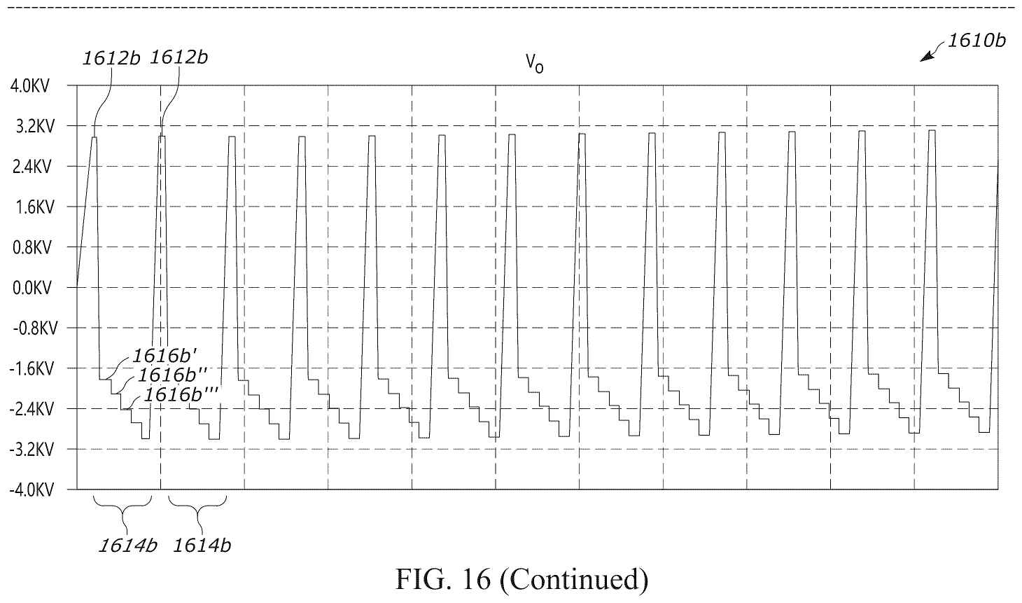

FIG. 16 shows a pair of waveforms 1610a, 1610b showing multiple cycles of output voltage Vo to depict two approaches to turning off or substantially reducing output of a power generator, such as bias generator 612b. Waveform 1610a shows output voltage Vo over multiple cycles 1612a. As described above with respect to FIG. 6, each power amplifier module 614b₁, . . . , 614b₍ₙ₋₁₎, 614bₙ generates approximately equal output voltages +V_{PA}, −V_{PA}, or 0 volts. With reference to bias generator 612b, upon turn off or substantial output reduction, output voltage Vo drops from just above 0.0 KV to approximately −4.5 KV. As can be seen at region 1614b, output voltage Vo oscillates in a general sawtooth pattern between −4.5 KV to −4.25 KV. Each power amplifier module 614b₁, . . . , 614b₍ₙ₋₁₎, 614bₙ generates approximately equal output voltages +V_{PA}, −V_{PA}, or 0 volts. When power amplifier modules 614b₁, . . . , 614b₍ₙ₋₁₎, 614bₙ are turned off or substantially simultaneously reduced, the pattern of region 1614a results.

Waveform 1610b shows output voltage Vo over multiple cycles 1612b. As described above with respect to FIGS. 11, 12, and 13, each respective bias generator 1114b, 1214b, 1314b includes respective fixed step generation sections 1114_{F}, 1214_{F}, 1314_{F} and variable step generation sections 1114_{V}, 1214_{V}, 1314_{V}. As described above with respect to respective FIGS. 11, 12, and 13, each power amplifier PA₁, . . . , PA₍ₙ₋₁₎, PAₙ of power amplifier modules of fixed step generation sections 1114_{F}, 1214_{F}, 1314_{F} generates approximately equal output voltages +V_{PA}, −V_{PA}, or 0 volts. Power amplifiers PA_{Vx} and PA_{Vy}; PA_{W1}, PA_{W2}, PA_{W(m-1)}, . . . . PA_{W(m)}; PA_{PWL} of respective variable step generation sections 1114_{V}, 1214_{V}, 1314_{V} generate output voltages that differ from the output voltages generated by the power amplifier modules of fixed step generation sections 1114_{F}, 1214_{F}, 1314_{F}. Further, the output voltages generated by each power amplifier module of variable step power generation sections 1114_{V}, 1214_{V} may vary from the output voltages generated by other power amplifier modules in the variable step power generation section.

Upon turn off, as can be seen at region 1614b, output voltage Vo decays in a stair step pattern. Region 1614b of waveform 1610b shows stair steps 1616b′, 1616b″, 1616b′″. The number of stair steps varies, as will be described below. Upon turn off, power amplifier modules of the fixed step generation sections 1114_{F}, 1214_{F}, 1314_{F} are deactivated or substantially reduced. Also upon turn off, power amplifier modules of variable step generation sections 1114_{V}, 1214_{V}, 1314_{V} are activated to provide the stair step patterns shown in region 1614b. In various configurations, fixed step generation sections 1114_{F}, 1214_{F}, and 1314_{F} may each include a first predetermined number of power amplifier modules. The output voltages of each activated power amplifier module are added in series to generate a respective fixed output voltage. In various configurations, variable step generation sections 1114_{V}, 1214_{V}, 1314_{V} include a second predetermined number of power amplifier modules. Further, in various configurations, power amplifier modules of variable step generation sections 1114_{V}, 1214_{V}, 1314_{V} are actuated to provide stair steps over a predetermined time period. The predetermined time period, in various configurations, may be measured from the deactivation of the power modules of fixed step generation sections 1114_{F}, 1214_{F}, 1314_{F}. In this manner, selective actuation of power amplifier modules of variable step generation sections 1114_{V}, 1214_{V}, 1314_{V} enable generation of quantized ramps to enable a gradual decrease in the voltage upon actuation or deactivation of the power modules of fixed step generation sections 1114_{F}, 1214_{F}, 1314_{F}. In the various configurations described above, output voltage Vo can be varied in accordance with several inputs. As described above, in various configurations, fixed step generation sections 1114_{F}, 1214_{F}, 1314_{F} generate an output voltage that varies in accordance with one or both of voltage Vs or the turns ratio of transformer 882. For example, voltage Vs may provide one input that determines the voltage output by each power amplifier module. Further, the turns ratio of transformer 882 also determines the voltage output by each power amplifier module. Further yet, selection of voltage Vs in combination with the turns ratio of transformer 882 further determines the voltage output by each power amplifier module.

As described above, in various configurations, variable step generation sections 1114_{V}, 1214_{V}, 1314_{V} may receive different voltages Vs generated in accordance with varying combinations of converter 772 and PS driver module 774 to thereby generate differing output voltages. Further, the turns ratio of transformer 882 also determines the voltage output by each power amplifier module. Further yet, selection of voltage Vs in combination with the turns ratio of transformer 882 further determines the voltage output by each power amplifier module of the power amplifier modules of variable step generation sections 1114_{V}, 1214_{V}, and 1314_{V}. Further, it should be recognized that while the stairstep pattern of waveform 1610b of FIG. 16 has been described in connection with a descending stairstep pattern, an ascending stairstep pattern can be implemented using a similar approach as described above.

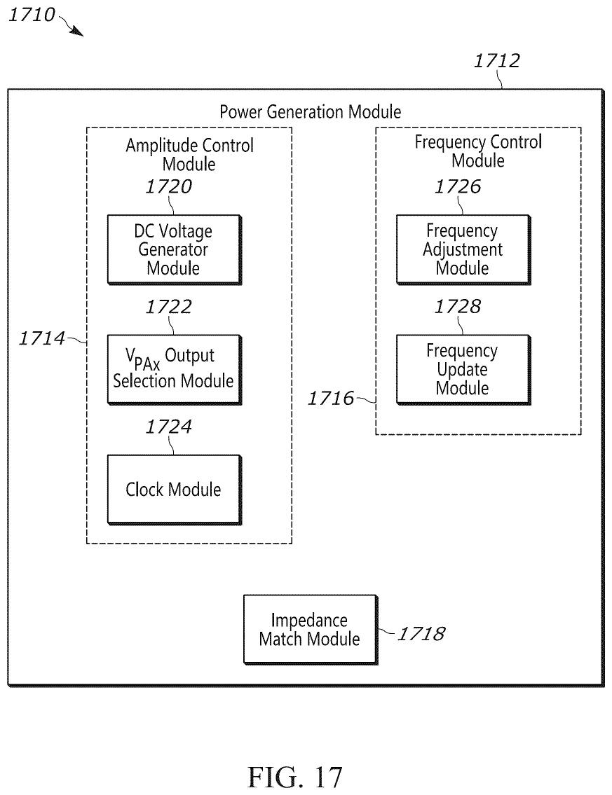

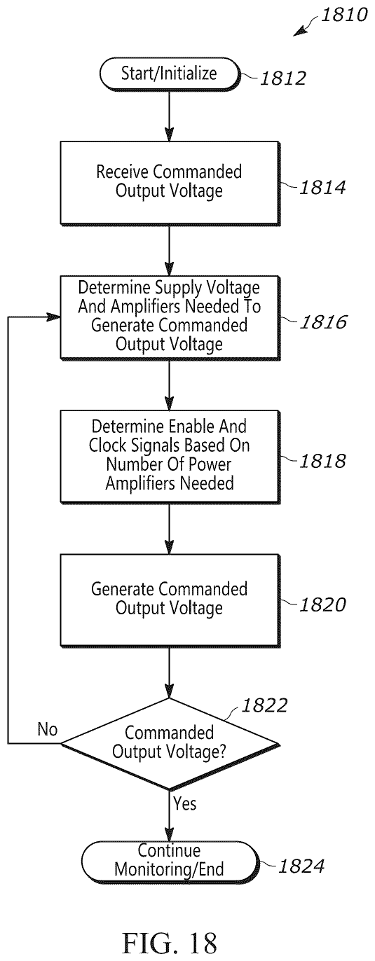

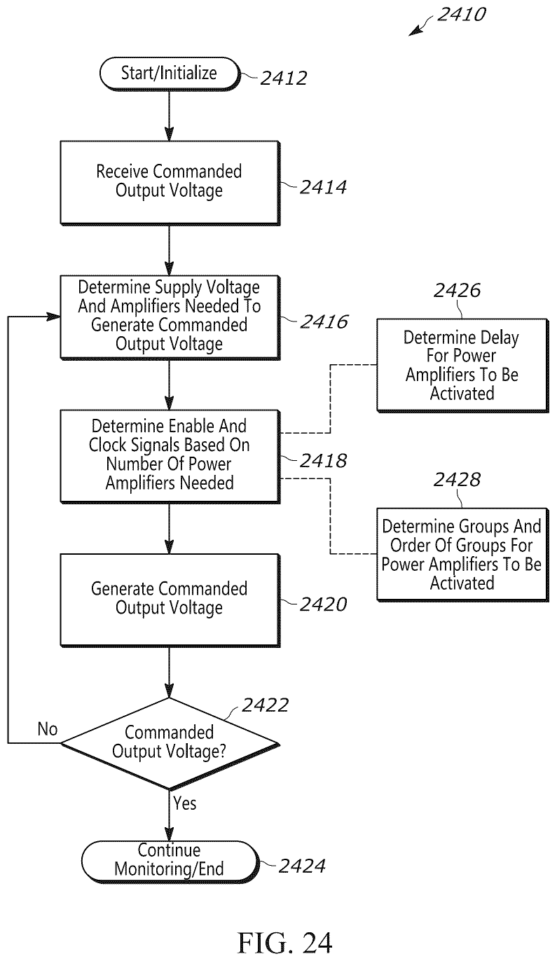

FIG. 17 incorporates various components of FIGS. 1-15. Control module 1710 may include power generation module 1712, including amplitude control module section 1714, duty cycle or frequency control module section 1716, and impedance match module 1718. Amplitude control module section 1714 includes DC voltage generator module 1720, V_{PAx} output selection module 1722, and clock module 1724. Frequency control module section 1716 includes frequency adjustment module 1726 and frequency update module 1728. In various configurations, control module 1710 includes one or a plurality of processors that execute code associated with the module sections or modules 1710, 1712, 1714, 1716, 1718, 1720, 1722, 1724, 1726, and 1728. Operation of the module sections or modules 1710, 1712, 1714, 1716, 1718, 1720, 1722, 1724, 1726, and 1728 is described below with respect to the method of FIGS. 18 and 24.

For further defined structure of controllers 120a, 120b, and 120′ and other controllers described in FIGS. 1-15, see the below provided flow chart of FIGS. 18 and 24 and the below provided definition for the term “module”. The systems disclosed herein may be operated using numerous methods, examples, and various control system methods of which are illustrated in FIG. 1. Although the following operations are primarily described with respect to the implementations of FIG. 1, the operations may be easily modified to apply to other implementations of the present disclosure. The operations may be iteratively performed. Although the following operations are shown and primarily described as being performed sequentially, one or more of the following operations may be performed while one or more of the other operations are being performed.

FIG. 18 shows a flow chart of a control system 1810 for performing voltage control for, in a nonlimiting example, the power delivery system of FIG. 1-15. Control begins at start/initialize block 1812. Control proceeds to block 1814 at which the commanded output voltage is received. Control proceeds to block 1816 where the supply voltage Vdc and the number of power amplifiers and which power amplifiers are needed to generate the commanded output voltage is determined. Control proceeds to block 1818 which determines the enable and clock signal to control the power amplifiers as determined in 1816 to generate the commanded output voltage. Control proceeds to block 1820 which generates the output voltage in accordance with the Clock and Enable signals by generating the Clock and Enable signals to each power amplifier. Control proceeds to block 1822 where it is determined whether the commanded output voltage has been achieved. If the commanded output voltage has not been achieved, control proceeds to block 1816 and repeats to update power amplifier control signals in order to advance towards the commanded output voltage. If the commanded output voltage has been achieved, control proceeds to block 1824 which ends the process but continues monitoring the output voltage.

Plasma loads are highly nonlinear and are prone to rapid load transients during plasma ignition, arcing, and pulsing. The bias generator described in this disclosure protects the generator, plasma chamber, and wafer from mismatched loads by detecting rapid changes in one or all of the load impedance, output voltage, and output current. Further, the generator described in this disclosure can be configured to protect the circuits from mismatched loads by rotating the power amplifiers of the fixed and variable power generation sections in and out of operation to prevent overheating. The rotation occurs at the zero-crossing of the power amplifier module output waveform and does not disturb the overall output of the bias generator. In the above-described generator, the fixed step generation section 1114_{F}, by way of nonlimiting example, is described as power amplifier modules 1114b₁, . . . , 1114b₍ₙ₋₁₎, 1114bₙ. Similarly, variable step generation section 1114_{V}, by way of nonlimiting example, is described as having a pair of power amplifier modules 1114b_{Vx} and 1114b_{Vy}, though more or fewer could be present. A similar approach to rotation of power amplifier modules may be applied to the power amplifier modules of variable step generation section 1114_{V}.

In various configurations, the total output voltage can be limited to a number less than the output voltage that the total number of power amplifiers can output. By way of nonlimiting example, if n=N+A, fixed step generation section 1114_{F} may include (N+A) power amplifiers, but no more than N power amplifiers of fixed step generation section 1114_{F} can be activated at one time. In such a configuration, operation of the (N+A) power amplifiers can be rotated so that all of the (N+A) power amplifiers have on periods and off periods in order to prevent overheating. In such a configuration, rotation occurs at zero crossing of the power amplifier output module waveform so as to not disturb the overall output of power generation system 1110. Similarly, variable step generation section 1114_{V}, by way of nonlimiting example, is described as having a pair of power amplifier modules 1114b_{Vx} and 1114b_{Vy}, though more or fewer could be present. A similar approach to rotation of power amplifier modules may be applied to the power amplifier modules of variable step generation section 1114_{V}.

In a conventional, phase shifted Class D power amplifier, such as may be implemented in the power amplifiers described herein, a typical failure involves the main power amplifier device shorting to ground, resulting in the loss of control and power. When such an event occurs in a wafer fabrication process, it is possible that the wafer may need to be scrapped. In the RF plasma generator of the present disclosure, an increased count of independent, identical amplifiers can produce improved granularity for redundancy. By way of nonlimiting example, the (N+A) power amplifiers described above create an additional inventory of A power amplifiers, enabling a power amplifier to be omitted from the rotation if it has failed. Accordingly, if a power amplifier has failed, the failed amplifier does not impact the remaining amplifiers. In various configurations, a fault sensor may be associated with each power amplifier in order to provide indication of a failure of a respective power amplifier at the time that it occurs. Further, in various configurations, each power amplifier is individually fused to isolate the power amplifier from the bulk voltage supply in the event of a short-circuit of that particular power amplifier. This allows voltage to remain uninterrupted to the other RF power amplifiers. Further, at the next zero crossing, the failed power amplifier is identified and switched out in favor of a replacement power amplifier in order to minimize any output disturbances.

The RF power generator described herein may provide one or more of the following benefits. The generator described herein addresses several challenges for bias generators used for HAR etching. The generator described herein improves IEDF spreading due to rectangular envelope and arbitrary bias waveform shaping capability. The generator described herein further reduces the size and weight of bias generator components mounted at the chamber. Further yet, the generator described herein improves power conversion efficiency for reduced cost of ownership (COO).

The power generator described herein provides higher power density, since a nonisolated, fixed voltage buck regulator may be used to generate Vdc. Such a voltage regulator is smaller than an isolated agile rail voltage supply. The RF power generator described herein provides improved pulsing performance, since it can enable generation of narrower pulses, higher peak/average power ratios, and complex envelopes due to faster actuation rates. The RF power generator described herein provides higher power efficiency during multilevel pulsing because power amplifier modules are either on or off, and no power is wasted during low power portions of the pulse envelope, since power amplifiers that are not needed are disabled. The RF power generator described herein enables alignment of power changes with the pulse state since the power amplifier inherently actuates amplitude changes aligned to pulse state changes, which improves plasma stability in a pulse mode of operation. The RF power generator described herein provides fast response time. The fast response time results from a constant voltage power supply powering all or groups of the power amplifiers. This eliminates the power supply control loop and resultant response time and removes turn on delay used in other designs. Series combined power amplifiers are enabled on/off in synchronization on every RF clock cycle and produce an output quantization step voltage.

In the various configurations described above with respect to FIG. 16 and, in particular, pulses or cycles 1612b, stair steps 1616b′, 1616b″, 1616b′″ typically are directed to slope compensation. By controlling the slope of descending (or ascending) waveforms, such as pulses or cycles 1612b, by providing stair steps 1616b′, 1616b″, 1616b′″, the slope of the transition can be controlled to various customer requirements. Further, in various configurations, a positive or negative transition of pulses or cycles 1612b can result in ringing or overshoot occurring during the transition as the DC voltage stabilizes. Ringing or overshoot in various applications may be undesirable.

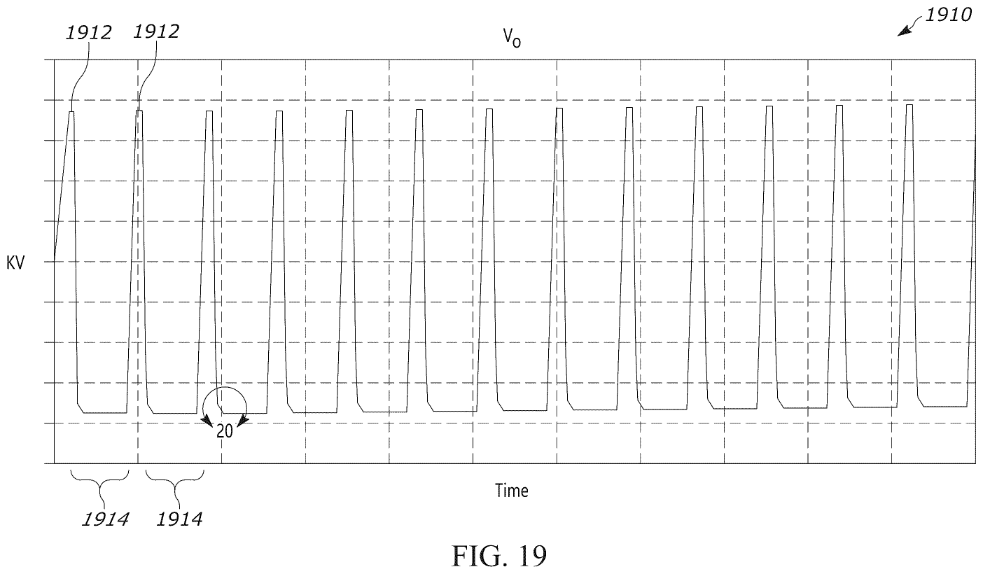

FIG. 19 shows waveform 1910 which is configured generally similar to waveform 1610b. Waveform 1910 includes multiple pulses or cycles 1912 which are generally similarly shaped to pulses or cycles 1612b of FIG. 16. As can be seen in FIG. 19, during a negative transition of cycle 1912 to a generally constant, negative DC voltage 1914, the negative transition to the generally constant, negative DC voltage 1914 occurs over a shorter or compressed time interval. Whereas in FIG. 16 pulses or cycles 1612b show a stairstep over region 1614b indicating a longer period of controlling, for example, power amplifier modules of variable step generation sections 1114_{V}, 1214_{V}, 1314_{V}, which are actuated to further increase the voltage negatively and provide the stair step pattern shown in region 1614b. As described above, if transition of Vo to a negative output voltage is desired, power amplifier modules of fixed step generation sections 1114_{F}, 1214_{F}, 1314_{F} are actuated to output a respective negative output voltage, such as −V_{PA} described above. This transition may occur by substantially actuating some or all power amplifier modules to output a negative output voltage, such as −V_{PA}. The stairstep pattern in region 1614b is achieved by actuating power amplifier modules of respective variable step generation sections 1114_{V}, 1214_{V}, 1314_{V} to output a negative output voltage (−V_{PA}) to further negatively increase output voltage Vo. While the approach described above in connection with waveform 1610b provides desirable slope compensation, further benefits can be achieved by timing actuation of negative output voltage (−V_{PA}) or positive output voltage (+V_{PA}) of, by way of nonlimiting example, one or more power amplifier modules of bias generator 612b or fixed step generation sections 1114_{F}, 1214_{F}, 1314_{F} to address ringing and overshoot. In various other configurations, further benefits can be achieved by timing actuation of negative output voltage (−V_{PA}) or positive output voltage (+V_{PA}) of, by way of nonlimiting example, one or more power amplifier modules of variable step generation sections 1114_{V}, 1214_{V}, 1314_{V} to address ringing and overshoot. In various other configurations, further benefits can be achieved by timing actuation of negative output voltage (−V_{PA}) or positive output voltage (+V_{PA}) of, by way of nonlimiting example, one or more power amplifier modules of both fixed step generation sections and variable step generation sections described above to address ringing and overshoot. In various configurations, actuation of negative output voltage (−V_{PA}) may be referred to as a negative cycle or pulse, and actuation toward positive output voltage (+V_{PA}) may be referred to as a positive cycle or pulse.

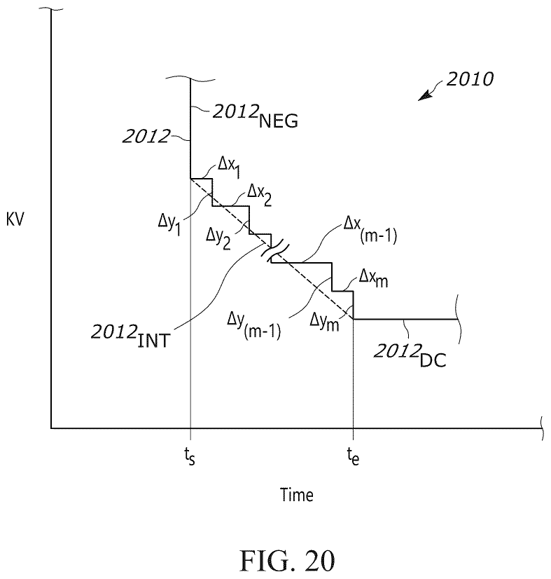

With reference to FIG. 20, waveform portion 2010 shows waveform pulse portion 2012 which is an expanded view of a portion of waveform 1910. Waveform pulse portion 2012 includes a negative transition portion 2012_{NEG}, an intermediate portion 2012_{INT}, and a generally constant or DC portion 2012_{DC}. Intermediate portion 2012_{INT} includes a stairstep section having varying time intervals Δx₁, Δx₂, . . . , Δx₍ₘ₋₁₎, Δxₘ. In various configurations, m may be equal to or less than the number of power amplifier modules of a power generation system, the number of fixed power amplifier modules of a fixed step generation section, the number of variable power amplifier modules of a variable step generation section, or some combination thereof. Similarly, intermediate portion 2012_{INT} includes a stairstep section having varying voltage intervals Δy₁, Δy₂, . . . , Δy₍ₘ₋₁₎, Δyₘ. In various configurations, m may be equal to or less than the number of power amplifier modules of a power generation system, the number of fixed power amplifier modules of a fixed step generation section, the number of variable power amplifier modules of a variable step generation section, or some combination thereof.

By way of comparison to region 1614b of FIG. 16, region 1614b substantially covers the time period between the start of a negative transition or negative cycle of a first pulse and the start of a positive transition or positive cycle of a succeeding pulse. Waveform pulse portion 2012, on the other hand, covers only a relatively small fraction of the time period between the start of a negative going transition of a first pulse and the start of a positive going transition of a succeeding pulse.

By way of nonlimiting example, the transition to the negative cycle commences at start time tₛ and terminates at end time tₑ. In FIG. 16, the interval between start time tₛ and end time tₑ is approximately equal to a substantial portion of the negative cycle of pulse or cycle 1612b, in FIGS. 19 and 20, the interval between start time tₛ and end time tₑ is substantially less. In some configurations, the interval between start time tₛ and end time tₑ may be barely perceptible in FIG. 19. In various configurations, intermediate portion 2012_{INT} of pulse or cycle 1912 appears linear due to the inherent time required by a circuit to respond to changes in voltage and current. Further, it should be appreciated that negative transition portion 2012_{NEG} indicates one or a plurality of power amplifier modules of a power generation system being actuated to output a negative output voltage, such as −V_{PA}. Time intervals Δx₁, Δx₂, . . . , Δx₍ₘ₋₁₎, Δxₘ are shown in FIG. 20 to indicate either fixed or variable phases, time delays, or time lags between deactuation, or actuation, of power amplifier modules of a power generation systems. In various configurations, one or more power amplifier modules may be turned off during a time interval Δx.

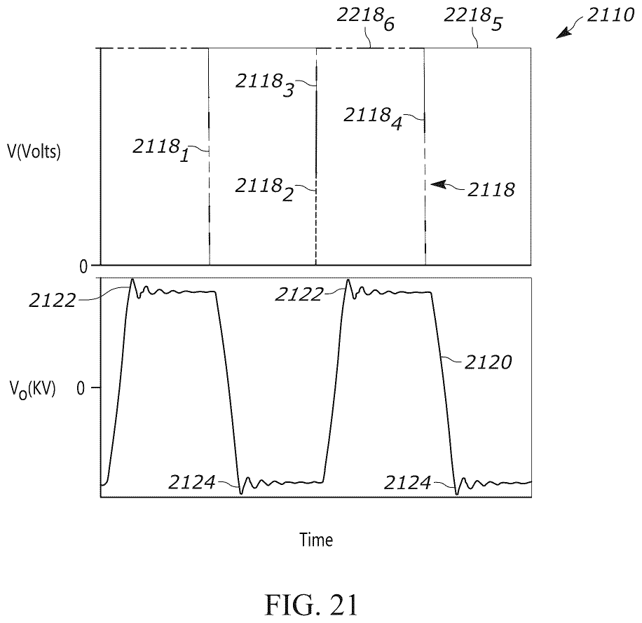

FIG. 21 shows waveforms including first waveform 2118 and second waveform 2120. First waveform 2118 generally represents actuation or deactuation of a power amplifier module, which may be controlled by the clock signal input to power amplifier control module 886 of FIG. 8. Second waveform 2120 generally represents output voltage Vo, as described above. First waveform 2118 includes a number of individual first waveforms 2118₁, 2118₂, . . . , 2118₆ which represent a commanded transition of selected power amplifier modules of a power generation system between negative output voltage (−V_{PA}) and positive output voltage (+V_{PA}). Individual first waveforms 2118₁, 2118₂, . . . , 2118₆ are generally coincident and appear as a single first waveform 2118. During a positive transition of first waveforms 2118₁, 2118₂, . . . , 2118₆, the voltage of second waveform 2120 transitions negative, and during a negative transition of first waveforms 2118₁, 2118₂, . . . , 2118₆, the voltage of second waveform 2120 transitions positive. It should be recognized that other relationships between first waveform 2118 and second waveform 2120 may be established. FIG. 21 is intended to show one example relationship between actuation of selected power amplifier modules and output voltage Vo.

Second waveform 2120 of FIG. 21 shows overshoot and ringing of voltage Vo during both the positive transitions and negative transitions. By way of nonlimiting example, during positive transition of second waveform 2120, overshoot and ringing of voltage Vo is shown at 2122. During negative transitions of second waveform 2120, overshoot and ringing of voltage Vo is shown at 2124.

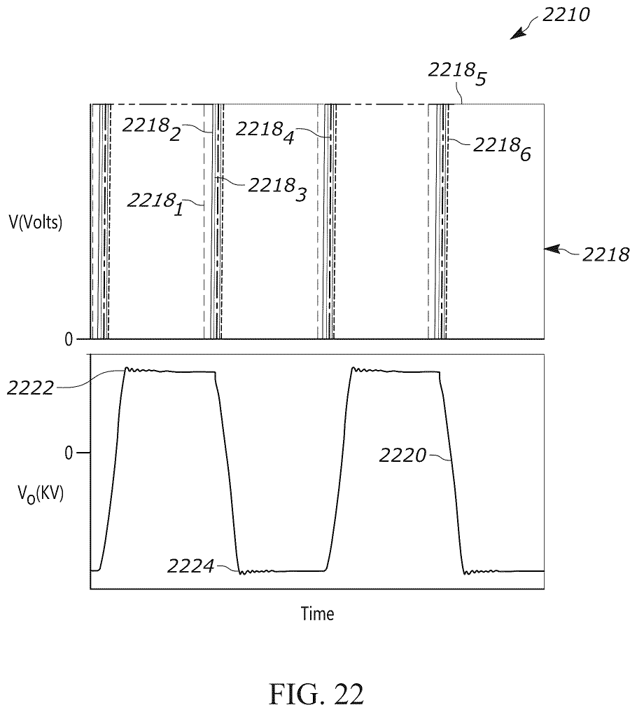

FIG. 22 shows waveforms including first waveform 2218 and second waveform 2220. First waveform 2218 and second waveform 2220 indicate similar parameters as described above with respect to FIG. 21. As can be seen in first waveform 2118, waveform 2218 includes a number of individual waveforms 2218₁, 2218₂, . . . , 2218₆ which represent a commanded transition of selected power amplifier modules of a power generation system between negative output voltage (−V_{PA}) and positive output voltage (+V_{PA}). As shown in waveform 2218, during positive transition of waveforms 2218₁, 2218₂, . . . , 2218₆, the voltage of waveform 2220 goes negative, and during negative transition of waveforms 2218₁, 2218₂, . . . , 2218₆, the voltage of waveform 2220 goes positive. Individual first waveforms 2218₁, 2218₂, . . . , 2218₆ are offset to provide a phase, time delay, or time lag, between first waveforms 2218₁, 2218₂, . . . , 2218₆. This phase, time delay, or time lag can be represented by Δx₁, Δx₂, . . . , Δx₍ₘ₋₁₎, Δxₘ of FIG. 20. FIG. 22 is intended to show one example relationship between actuation of selected power amplifier modules and the output voltage Vo. As can be seen in FIGS. 20 and 22, phase, time delay, or time lag between actuating or deactuating power amplifier modules is substantially less than that shown in FIG. 16.

Second waveform 2220 of FIG. 22 shows that the time delayed or phased actuation or deactuation of power modules associated with respective first waveforms 2218₁, 2218₂, . . . , 2218₆ significantly reduces overshoot and ringing of voltage Vo during both positive transitions and negative transitions. By way of nonlimiting example, during positive transition of second waveform 2120, overshoot and ringing of voltage Vo is significantly reduced as shown at region 2222. Similarly, during negative transition of waveforms 2220, overshoot and ringing of voltage Vo is shown at region 2224.

In various configurations, ringing and overshoot may be sensed, obtained, measured, or detected, collectively referred to as sensed, at various locations of the power generation system. By way of nonlimiting example with respect to power generation system 610 of FIG. 6, in various applications, it may be desirable to sense ringing and overshoot in voltage Vo at one or more of the output of generator 612b, the input to matching and filter network 618, or the input to load 632. Rather than deploying sensors in each of these locations throughout power generation system 610, a virtual sensor may be deployed to provide parameters indicative of ringing and overshoot, such as power, voltage, or current. The virtual sensor utilizes selected parameters of the power generation system and applies a model of the plasma generation system to determine parameters of interest at various locations through the power generation system. An example of a virtual sensor can be found with respect to U.S. patent application Ser. No. 17/715,672, filed Aug. 10, 2022, entitled Real-Time Non-Invasive IEDF Plasma Sensor, assigned to the assignee of the present application, and incorporated by reference herein.

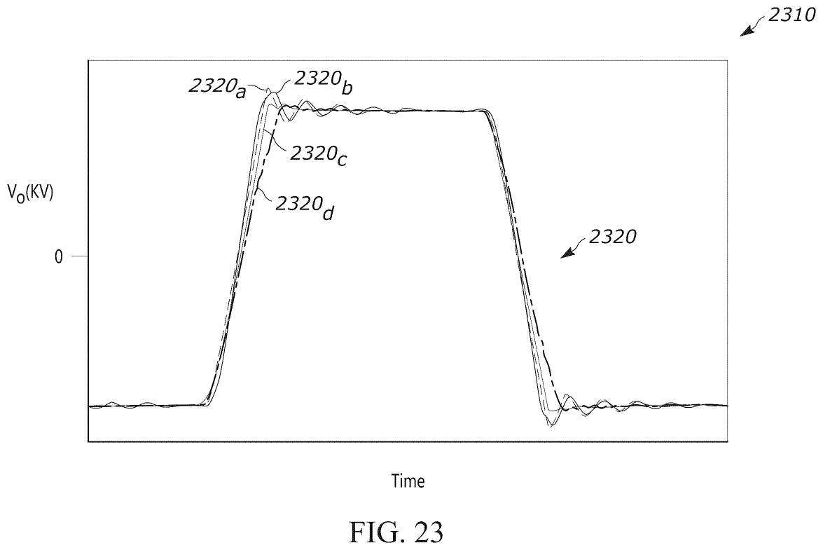

FIG. 23 shows various waveforms of voltage Vo to describe variation in ringing, overshoot, and slope compensation. FIG. 23 shows waveforms 2310, which includes waveform Vo 2320. By way of nonlimiting example, a plurality of variations of waveform Vo 2320 is shown by waveforms 2220ₐ, 2320_{b}, 2320_{c}, 2320_{d}. Waveform 2220ₐ shows a waveform with a high slope and the most ringing and overshoot of the waveforms of waveform Vo 2320. Waveform 2220_{b} shows a waveform with a slightly greater slope than waveform 2320ₐ, but with less ringing and overshoot. Waveform 2220, shows a waveform with less slope and no ringing or overshoot. Waveform 2220_{d} shows a waveform with the least slope and no ringing or overshoot.

In various configurations, waveforms 2220ₐ, 2320_{b}, 2320_{c}, 2320_{d} can be obtained by varying the phase, time delay, or time lag between actuation or deactuation of one or more power amplifier modules of a power generation system. In the particular example of FIG. 23, minimal ring or overshoot is selected from one of waveforms 2320_{c} or 2320_{d} depending on the desired slope of the rising or falling edge of waveform Vo 2320. In various configurations, a phase, time delay, or time lag between actuation or deactuation of the power amplifier modules can be determined by introducing perturbation signals into the output of each power amplifier module, such power amplifier modules of 612b, 1114_{F}, 1214_{F}, 1314_{F}, by way of nonlimiting example. An iterative learning control approach may be used to adjust the phase, time delay, or time lag to minimize or maximize a parameter or cost varying in response to the perturbation. The various time delay or phase lag determination methods described above are described in one or more of U.S. Pat. No. 10,741,363, issued Aug. 11, 2020, entitled Extremum Seeking Control Apparatus and Method for Automatic Frequency Tuning for RF Impedance Matching; and U.S. Pat. No. 11,527,384, issued Dec. 13, 2022, entitled Apparatus and Tuning Method for Mitigating RF Load Impedance Variations Due to Periodic Disturbances, both assigned to the assignee of the present application, and incorporated by reference herein.

The above-described power amplifier modules output a voltage and a current. The voltage output by the above-described power amplifier modules is fairly accurate relative to the nominal, expected output of the power amplifier modules. However, in the above-described configurations of the power generation systems, the various power amplifier modules may output different current values. In various configurations, the current output, or current consumed, of a power amplifier module may vary. Variations in the current results in a corresponding variation in output power of a particular power module, as power is defined as voltage multiplied by current (P=VI). In various configurations, power output by a particular power amplifier module can vary from 50% to 150% of the nominal expected power output, based on nominal expected output voltage V and nominal expected output current I. Variation in current results in unequal power sharing between the power amplifier modules. Unequal power sharing between power amplifier modules can result in unequal stress experienced by power amplifier modules outputting higher power than nominal expected output power.

In various configurations, power-sharing can be controlled by forming a plurality of groups of one or more power amplifier modules and actuating the groups in a predetermined order. By way of nonlimiting example, if there are eight power amplifier modules PA₁, PA₂, . . . PA₇, PA₈, one or more groups of one or more of the eight power amplifier modules may be formed to improve power-sharing. Further by way of nonlimiting example, the groups of power amplifier modules can be formed as follows: {PA₂, PA₃, PA₄, PA₇}, {PA₁, PA₈}, and {PA₅, PA₆}, though other groups could be formed and the number of power amplifier modules in each group can vary. The groups of power amplifier modules can be actuated in a predetermined order to output negative output voltage (−V_{PA}) or positive output voltage (+V_{PA}). By way of nonlimiting example, the groups may be actuated in the following order: {PA₅, PA₆}; followed by {PA₂, PA₃, PA₄, PA₇}; followed by {PA₁, PA₈}. In various configurations, each power amplifier module can be characterized by the power that it consumes and the groups may be formed based on relative power consumption. In various configurations, it may be desirable for groups having power amplifier modules that consume less power activated prior to groups having power amplifier modules that consume more power.

FIG. 24 shows a flow chart of a control system 1810 for performing voltage control for, in a nonlimiting example, the power delivery system of FIGS. 1-15. FIG. 24 generally operates as described above with respect to FIG. 18, but includes control for varying the timing between or order of actuation or deactuation of the power amplifier modules to control one or more of ringing, overshoot, and power sharing. Control begins at start/initialize block 2412. Control proceeds to block 2414 at which the commanded output voltage is received. Control proceeds to block 2416 where the supply voltage Vdc and the number of power amplifiers and which power amplifiers are needed to generate the commanded output voltage is determined. Control proceeds to block 2418 which determines the enable and clock signal to control the power amplifiers as determined at block 2416 to generate the commanded output voltage.

At block 2418, in addition to determining the enable and the clock signals based on the number of amplifiers needed, at least one of the relative timing of actuation of the power amplifier modules between negative output voltage (−V_{PA}) and positive output voltage (+V_{PA}) and the grouping and order of actuation between negative output voltage (−V_{PA}) and positive output voltage (+V_{PA}) of the groups of power amplifier modules is determined. In various configurations, the phase, time delay, or time lag between actuation of the power amplifier modules is determined at block 2426. In various configurations, the grouping and order of actuation between negative output voltage (−V_{PA}) and positive output voltage (+V_{PA}) of the power amplifier modules may be determined using an iterative learning control approach as described above. Similarly, in various configurations, the grouping and order of actuation or deactuation of the power amplifier modules is determined at block 2428. In various configurations, the grouping and order of actuation or deactuation of the power amplifier modules be determined using an iterative learning control approach as described above. In various configurations, blocks 2426 and block 2428 operate independently. In various other configurations, blocks 2426 and block 2428 operate cooperatively in connection with determining the phase, time delay, or time lag between actuation of the power amplifier modules.

Control proceeds to block 2420 which generates the output voltage in accordance with the Clock and Enable signals by generating the Clock and Enable signals to each power amplifier. Control proceeds to block 2422 where it is determined whether the commanded output voltage has been achieved. If the commanded output voltage has not been achieved, control proceeds to block 2416 and repeats to update power amplifier control signals in order to advance towards the commanded output voltage. If the commanded output voltage has been achieved, control proceeds to block 2424 which ends the process but continues monitoring the output voltage.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. In the written description and claims, one or more steps within a method may be executed in a different order (or concurrently) without altering the principles of the present disclosure. Similarly, one or more instructions stored in a non-transitory computer-readable medium may be executed in a different order (or concurrently) without altering the principles of the present disclosure. Unless indicated otherwise, numbering or other labeling of instructions or method steps is done for convenient reference, not to indicate a fixed order.

Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements.

The phrase “at least one of A, B, and C” should be construed to mean a logical (A OR B OR C), using a non-exclusive logical OR, and should not be construed to mean “at least one of A, at least one of B, and at least one of C.” The term “set” does not necessarily exclude the empty set—in other words, in some circumstances a “set” may have zero elements. The term “non-empty set” may be used to indicate exclusion of the empty set—in other words, a non-empty set will always have one or more elements. The term “subset” does not necessarily require a proper subset. In other words, a “subset” of a first set may be coextensive with (equal to) the first set. Further, the term “subset” does not necessarily exclude the empty set—in some circumstances a “subset” may have zero elements.

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” can be replaced with the term “controller” or the term “circuit.” In this application, the term “controller” can be replaced with the term “module.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); processor hardware (shared, dedicated, or group) that executes code; memory hardware (shared, dedicated, or group) that stores code executed by the processor hardware; other suitable hardware components that provide the described functionality; or a combination of some or all of the above, such as in a system-on-chip.

The module may include one or more interface circuits. In some examples, the interface circuit(s) may implement wired or wireless interfaces that connect to a local area network (LAN) or a wireless personal area network (WPAN). Examples of a LAN are Institute of Electrical and Electronics Engineers (IEEE) Standard 802.11-2020 (also known as the WIFI wireless networking standard) and IEEE Standard 802.3-2018 (also known as the ETHERNET wired networking standard). Examples of a WPAN are IEEE Standard 802.15.4 (including the ZIGBEE standard from the ZigBee Alliance) and, from the Bluetooth Special Interest Group (SIG), the BLUETOOTH wireless networking standard (including Core Specification versions 3.0, 4.0, 4.1, 4.2, 5.0, and 5.1 from the Bluetooth SIG).

The module may communicate with other modules using the interface circuit(s). Although the module may be depicted in the present disclosure as logically communicating directly with other modules, in various implementations the module may actually communicate via a communications system. The communications system includes physical and/or virtual networking equipment such as hubs, switches, routers, and gateways. In some implementations, the communications system connects to or traverses a wide area network (WAN) such as the Internet. For example, the communications system may include multiple LANs connected to each other over the Internet or point-to-point leased lines using technologies including Multiprotocol Label Switching (MPLS) and virtual private networks (VPNs).

In various implementations, the functionality of the module may be distributed among multiple modules that are connected via the communications system. For example, multiple modules may implement the same functionality distributed by a load balancing system. In a further example, the functionality of the module may be split between a server (also known as remote, or cloud) module and a client (or, user) module. For example, the client module may include a native or web application executing on a client device and in network communication with the server module.

Some or all hardware features of a module may be defined using a language for hardware description, such as IEEE Standard 1364-2005 (commonly called “Verilog”) and IEEE Standard 1076-2008 (commonly called “VHDL”). The hardware description language may be used to manufacture and/or program a hardware circuit. In some implementations, some or all features of a module may be defined by a language, such as IEEE 1666-2005 (commonly called “SystemC”), that encompasses both code, as described below, and hardware description.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

The memory hardware may also store data together with or separate from the code. Shared memory hardware encompasses a single memory device that stores some or all code from multiple modules. One example of shared memory hardware may be level 1 cache on or near a microprocessor die, which may store code from multiple modules. Another example of shared memory hardware may be persistent storage, such as a solid state drive (SSD), which may store code from multiple modules. Group memory hardware encompasses a memory device that, in combination with other memory devices, stores some or all code from one or more modules. One example of group memory hardware is a storage area network (SAN), which may store code of a particular module across multiple physical devices. Another example of group memory hardware is random access memory of each of a set of servers that, in combination, store code of a particular module.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Nonlimiting examples of a non-transitory computer-readable medium are nonvolatile memory devices (such as a flash memory device, an erasable programmable read-only memory device, or a mask read-only memory device), volatile memory devices (such as a static random access memory device or a dynamic random access memory device), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. Such apparatuses and methods may be described as computerized apparatuses and computerized methods. The functional blocks and flowchart elements described above serve as software specifications, which can be translated into the computer programs by the routine work of a skilled technician or programmer.

The computer programs include processor-executable instructions that are stored on at least one non-transitory computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, JavaScript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A power generator, comprising:
a first plurality of power amplifiers, including:
a first power amplifier configured to receive a first supply voltage and to output a plurality of DC voltages; and
a second power amplifier configured to receive the first supply voltage and to output the plurality of DC voltages,
wherein the first power amplifier and the second power amplifier are connected in series and the power generator generates an output voltage that varies in accordance with a one of the plurality of DC voltages output by the first power amplifier and a one of the plurality of DC voltages output by the second power amplifier.

2. The power generator of claim 1 wherein the first power amplifier and the second power amplifier are controlled to output a carrier signal, and further wherein the first power amplifier and the second power amplifier are further controlled to pulse the carrier signal.

3. The power generator of claim 2 wherein the carrier signal is at least one of a sinusoidal, rectangular, nonsinusoidal, or piecewise linear waveform.

4. The power generator of claim 3 wherein the pulse is one of a rectangular, trapezoidal, triangular, sawtooth, or gaussian pulse waveform.

5. The power generator of claim 4 wherein the pulse includes a plurality of states.

6. The power generator of claim 2 wherein the pulse is one of a rectangular, trapezoidal, triangular, sawtooth, or gaussian waveform.

7. The power generator of claim 1 wherein one of the plurality of power amplifiers is actuated at a first time and an other of the plurality of power amplifiers is actuated at a second time.

8. The power generator of claim 7 wherein a time delay between the first time and the second time controls one of ringing, overshoot, or power sharing of the output voltage.

9. The power generator of claim 1 wherein each of the plurality of power amplifiers is characterized and grouped, and the groups are actuated in a predetermined order to control power sharing.

10. The power generator of claim 1 further comprising a first control module configured to generate a voltage output command for a selected one of the first plurality of power amplifiers, wherein the voltage output command determines which one of the plurality of DC voltages is output by the selected one of the first plurality of power amplifiers.

11. The power generator of claim 10 wherein the first control module is further configured to generate a voltage output command for an other of the first plurality of power amplifiers, wherein the voltage output command determines which one of the plurality of DC voltages is output by the other of the first plurality of power amplifiers.

12. The power generator of claim 10 further comprising a second control module configured to generate a voltage output command for an other of the first plurality of power amplifiers, wherein the voltage output command determines which one of the plurality of DC voltages is output by the other of the first plurality of power amplifiers.

13. The power generator of claim 1 wherein the first plurality of power amplifiers comprises a fixed step generation section, and the power generator further comprises a variable step generation section including a first variable power amplifier configured to receive a second supply voltage and to output a second plurality of DC voltages that differs from the plurality of DC voltages.

14. The power generator of claim 13 wherein the variable step generation section comprises:
a second plurality of power amplifiers, including:
the first variable power amplifier; and
a second variable power amplifier configured to receive a third supply voltage and to output a third plurality of DC voltages,
wherein the first variable power amplifier and second variable power amplifier are connected in series, and connected in series with the fixed step generation section, and the power generator generates an output voltage that varies in accordance with a one of the second plurality of DC voltages output by the first variable power amplifier, a one of the third plurality of DC voltages output by the second variable power amplifier, and the output of the fixed step generation section.

15. The power generator of claim 13 wherein the first variable power amplifier is configured to receive a second supply voltage and to output a piecewise linear output voltage, and wherein the first variable power amplifier is connected in series with the fixed step generation section, and the power generator generates an output voltage that varies in accordance with the piecewise linear output voltage and the output voltage of the fixed step generation section.

16. The power generator of claim 1 wherein the first plurality of power amplifiers outputs a bipolar voltage signal, and the power generator further comprises a DC charge pump receiving the output voltage of the first plurality of power amplifiers, and the DC charge pump is configured to convert the bipolar voltage signal to a unipolar voltage signal.

17. The power generator of claim 1 wherein components of the power generator are disposed in one of a remote module or a proximity module, and a proximity module is placed in proximity to a load, and the remote module is placed remotely from the load.

18. The power generator of claim 17 wherein the proximity module includes switching components of the first plurality of power amplifiers, and the remote module includes components for generating the first supply voltage.

19. The power generator of claim 1 further comprising a power supply driver that receives the first supply voltage and generates an alternating direct current signal applied to each of the first plurality of power amplifiers.

20. The power generator of claim 1 wherein the plurality of DC voltages includes at least two of +V_{PA}, −V_{PA}, or 0 volts, where +V_{PA1} and −V_{PA1} vary in accordance with the supply voltage.

21. A power generation system, comprising:
a first power source;
a second power source including a first plurality of power amplifiers, including:
a first power amplifier configured to receive a first supply voltage and to output at least two of +V_{PA1}, −V_{PA1}, or 0 volts, wherein +V_{PA1} and −V_{PA1} vary in accordance with the first supply voltage; and
a second power amplifier configured to receive a second supply voltage and to output at least two of +V_{PA2}, −V_{PA2}, or 0 volts, wherein +V_{PA2} and −V_{PA2} vary in accordance with the second supply voltage,
wherein the first power amplifier and the second power amplifier are connected in series and the power generator generates an output voltage that varies in accordance with the at least two of +V_{PA1}, −V_{PA1}, or 0 volts output by the first power amplifier and the at least two of +V_{PA1}, −V_{PA1}, or 0 volts output by the second power amplifier, and
wherein the first power supply and second power supply may be a single power supply or different power supplies and output equal or different voltages, and +V_{PA1}, −V_{PA1} may be equal to or different than +V_{PA2}, −V_{PA2}.

22. The power generation system of claim 21 wherein the first power amplifier and the second power amplifier are controlled to output a carrier signal, and further wherein the first power amplifier and the second power amplifier are further controlled to pulse the carrier signal.

23. The power generation system of claim 22 wherein the carrier signal is at least one of a sinusoidal, rectangular, nonsinusoidal, or piecewise linear waveform, and the pulse is one of a rectangular, trapezoidal, triangular, sawtooth, or gaussian pulse waveform.

24. The power generation system of claim 22 wherein one of the plurality of power amplifiers is actuated at a first time and an other of the plurality of power amplifiers is actuated at a second time.

25. The power generation system of claim 21 wherein the first plurality of power amplifiers comprises a fixed step generation section, and the power generator further comprises:
a variable step generation section including at least one variable power amplifier configured to receive at least one third supply voltage and to output a second plurality of DC voltages that differs from +V_{PA1}, −V_{PA1}, +V_{PA2}, and −V_{PA2},
wherein the variable step generation section is connected in series with the fixed step generation section, and the power generator is configured to generate an output voltage that varies in accordance with the second plurality of DC voltages and the output voltage.

26. A non-transitory computer-readable medium storing instructions, the instructions comprising:
generating at least two of +V_{PA1}, −V_{PA1}, or 0 volts from a first power amplifier receiving a first supply voltage, wherein +V_{PA1} and −V_{PA1} vary in accordance with the first supply voltage; and
generating at least two of +V_{PA2}, −V_{PA2}, or 0 volts, wherein +V_{PA2} and −V_{PA2} are output from a second power amplifier receiving a second supply voltage, wherein +V_{PA2} and −V_{PA2} vary in accordance with the second supply voltage,
generating an output voltage that varies in accordance with one of the at least two of +V_{PA1}, −V_{PA1}, or 0 volts output by the first power amplifier and one of the at least two of +V_{PA2}, −V_{PA2}, or 0 volts output by the second power amplifier, and
wherein the first supply voltage and the second supply voltage may be equal or different, and +V_{PA1}, −V_{PA1} may be equal to or different than +V_{PA2}, −V_{PA2}.

27. The non-transitory computer-readable medium storing instructions of claim 26, the instructions further comprising generating the output voltage including a carrier signal and a pulse, wherein the pulse modulates the carrier signal.

28. The non-transitory computer-readable medium storing instructions of claim 27 wherein the carrier signal is at least one of a sinusoidal, rectangular, nonsinusoidal, or piecewise linear waveform, and the pulse is one of a rectangular, trapezoidal, triangular, sawtooth, or gaussian pulse waveform.

29. The non-transitory computer-readable medium storing instructions of claim 27, the instructions further comprising actuating the first power amplifier at a first time and actuating the second power amplifier at a second time.

30. The non-transitory computer-readable medium storing instructions of claim 26 wherein one of the at least two of +V_{PA1}, −V_{PA1}, or 0 volts from the first power amplifier and one of the at least two of +V_{PA2}, −V_{PA2}, or 0 volts output by the second power amplifier are connected in series to comprise a fixed step voltage, the instructions further comprising:
generating a variable step voltage, wherein a variable voltage is output from a third power amplifier receiving a third supply voltage, wherein the variable step voltage is different than +V_{PA1}, −V_{PA1}, +V_{PA2}, and −V_{PA2},
wherein the variable step voltage is connected in series with the fixed step voltage, and
and wherein the third supply voltage may be equal to or different than the first supply voltage and the second supply voltage.
